(19) United States
(12) Patent Application Publication
(10) Pub. No.: US 2026/0130148 A1
(43) Pub. Date: May 7, 2026

(54) METHOD FOR PATTERN MODIFICATION AND EXTENSION

(71) Applicant: TEL Manufacturing and Engineering of America, Inc., Chaska, MN (US)

(72) Inventors: Luis Fernandez, North Chelmsford, MA (US); Atsushi Tsuboi, Leuven (BE); Ken Ando, Leuven (BE); Robert William Heussner, Hillsboro, OR (US); Chimaobi Mbanaso, Chaska, MN (US); Arame Thiam, Leuven (BE); Yannick Feurprier, Leuven (BE); Hung-Yu Chang, Albany, NY (US)

(21) Appl. No.: 19/345,931

(22) Filed: Sep. 30, 2025

Related U.S. Application Data
(60) Provisional application No. 63/717,792, filed on Nov. 7, 2024.

(51) Int. Cl. H01L 21/311; H01L 21/67

(52) U.S. Cl. CPC H10P 50/73; H10P 50/283; H10P 50/287; H10P 72/0421

(57) ABSTRACT

A method for processing a substrate includes receiving the substrate including a patterned mask disposed over a layer stack including a second layer disposed over a first layer, the patterned mask including a feature pattern, and etching the substrate to transfer the feature pattern to the second layer and form first openings that expose the first layer. The method further includes exposing a first sidewall of the first openings to a first focused beam at a first processing angle to extend the first openings in a first direction and form second openings, and etching the substrate to transfer the second openings through the first layer and form third openings. And the method further includes exposing the first sidewall of the third openings to a second focused beam at a second processing angle to form fourth openings.

### CROSS-REFERENCE TO RELATED APPLICATIONS

This application claims the benefit of U.S. Provisional Application No. 63/717,792, filed on Nov. 7, 2024, which application is hereby incorporated herein by reference.

### TECHNICAL FIELD

The present invention relates generally to semiconductor device fabrication, and, in particular embodiments, to systems and methods for pattern modification using critical dimension (CD) modification techniques.

### BACKGROUND

Semiconductor device fabrication involves creating intricate patterns of conductive, insulating, and semiconducting materials on substrates to form integrated circuits. Pattern formation typically involves depositing various material layers, applying photoresist, performing lithographic exposure, developing the resist, and transferring the pattern through etching processes. The substrate is first coated with resist and then exposed to actinic radiation to chemically alter the solubility of different regions of the mask. The exposed mask is developed to reveal the mask pattern comprising open (via, trench, e.g.) and closed (line, pillar, mandrel, e.g.) features which may be used as an etch mask to transfer the features to underlying layers of the substrate.

### SUMMARY

In accordance with an embodiment of this disclosure, a method for processing a substrate includes receiving the substrate including a patterned mask disposed over a layer stack including a second layer disposed over a first layer, the patterned mask including a feature pattern, and etching the substrate to transfer the feature pattern to the second layer and form first openings that expose the first layer, the first openings including a first critical dimension. The method further includes exposing a first sidewall of the first openings to a first focused beam at a first processing angle for a first processing time to extend the first openings in a first direction and form second openings, the second openings including a second critical dimension larger than the first critical dimension, and etching the substrate to transfer the second openings through the first layer and form third openings, the third openings including the second critical dimension. And the method further includes exposing the first sidewall of the third openings to a second focused beam at a second processing angle for a second processing time to form fourth openings, the fourth openings including a third critical dimension larger than the first critical dimension and the second critical dimension.

In accordance with another embodiment of this disclosure, a method for pattern modification includes receiving a substrate including a patterned layer with first pattern features including a first geometry, and exposing the patterned layer to a focused beam at a first processing angle for a first processing time to extend the first pattern features in a first direction and form extended pattern features. And the method further includes, after the first processing time, exposing the extended pattern features to the focused beam at a second processing angle different from the first processing angle for a second processing time to further extend the extended pattern features in a second direction and form modified pattern features, the second direction being different from the first direction, the modified pattern features including a second geometry different from the first geometry.

And in accordance with yet another embodiment of this disclosure, a system for patterning a substrate includes a processing chamber including a processing tool and a substrate holder, the processing tool configured to emit a focused beam, a scanning tool coupled to the substrate holder in the processing chamber, the scanning tool configured to scan the substrate holder along a plane that is parallel with a surface of the substrate holder that is tilted at a processing angle relative to a beam direction of the processing tool, and a controller coupled to the scanning tool, the processing tool, and a memory storing instructions to be executed in the controller. The instructions when executed enable the controller to receive the substrate including a patterned mask disposed over a layer stack including a second layer disposed over a first layer on the substrate holder, the patterned mask including a feature pattern, etch the substrate to transfer the feature pattern to the second layer and form first openings that expose the first layer, the first openings including a first critical dimension, expose a first sidewall of the first openings to a first focused beam at a first processing angle for a first processing time to extend the first openings in a first direction and form second openings using the processing tool, the second openings including a second critical dimension larger than the first critical dimension, etch the substrate to transfer the second openings through the first layer and form third openings, the third openings including the second critical dimension, and expose the first sidewall of the third openings to a second focused beam at a second processing angle for a second processing time to form fourth openings using the processing tool, the fourth openings including a third critical dimension larger than the first critical dimension and the second critical dimension.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1H each illustrate a cross-sectional side view and a top view of a substrate during steps of a critical dimension (CD) modification process in accordance with embodiments of this disclosure;

FIG. 2 is a flowchart of a method for performing a CD modification process in accordance with embodiments of this disclosure;

FIG. 3 illustrates a cross-sectional side view and a top view of a substrate processed using the CD modification process of FIGS. 1A-1H in accordance with an embodiment of this disclosure;

FIGS. 4A-4B each illustrate a top view of a substrate to show improved pitch control of the method for performing the CD modification process in accordance with embodiments of this disclosure;

FIGS. 5A-5K each illustrate a cross-sectional side view and a top view of a substrate during steps of a CD modification process in accordance with embodiments of this disclosure;

FIG. 6 is a flowchart of a method for performing a CD modification process in accordance with embodiments of this disclosure;

FIGS. 7A-7B each illustrate a cross-sectional side view and a top view of a substrate at different steps of the CD modification process of FIGS. 5A-5K to show critical dimension changes in accordance with embodiments of this disclosure;

FIG. 8 is a schematic diagram of a processing system which may be used to perform a CD modification process in accordance with embodiments of this disclosure;

FIG. 9 is a flowchart of a method for processing a substrate in accordance with embodiments of this disclosure; and FIG. 10 is a flowchart of a method for performing a CD modification process on a substrate in accordance with embodiments of this disclosure.

### DETAILED DESCRIPTION OF ILLUSTRATIVE EMBODIMENTS

Traditional lithographic techniques face resolution limits that constrain the minimum achievable pitch between pattern features. Alternative patterning approaches that can circumvent these lithographic limitations are valuable for continued device scaling and performance improvement.

Embodiments of the disclosure provide methods and systems for pattern transformation using directional beam processing to achieve pitch reduction and critical dimension modification in semiconductor manufacturing. The disclosed techniques enable the conversion of contact hole patterns into line-space patterns with significantly reduced pitch through sequential focused beam processing operations. The process utilizes controlled beam angles and multiple processing steps to directionally extend pattern features and create interconnected structures.

In various embodiments, the pattern transformation process begins with forming initial openings in a patterned layer disposed over a substrate. The openings are then subjected to directional beam processing at a first incident angle to extend the openings in a first direction. Subsequent processing steps may be performed at different beam angles to further extend the openings in the same or different directions. The extended openings can be connected through additional processing to form continuous line patterns with reduced pitch compared to the original pattern.

The disclosed approach provides several advantages over conventional patterning techniques. The multi-step directional processing enables precise control over pattern dimensions and pitch scaling. The technique can achieve pitch reductions that exceed the capabilities of traditional lithographic processes. The method also allows for the creation of complex interconnected patterns from simpler initial geometries, providing design flexibility for advanced semiconductor devices.

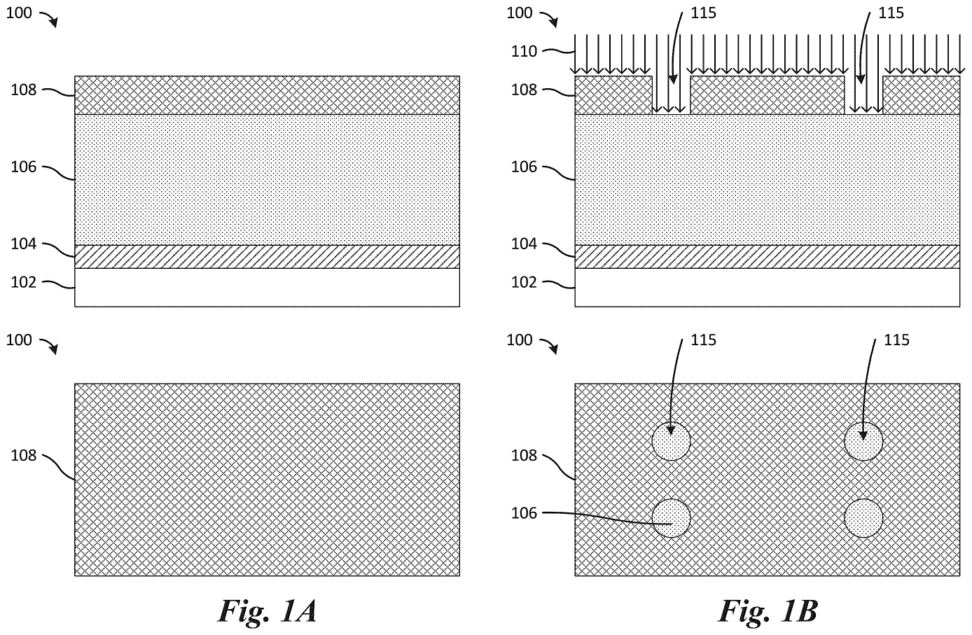

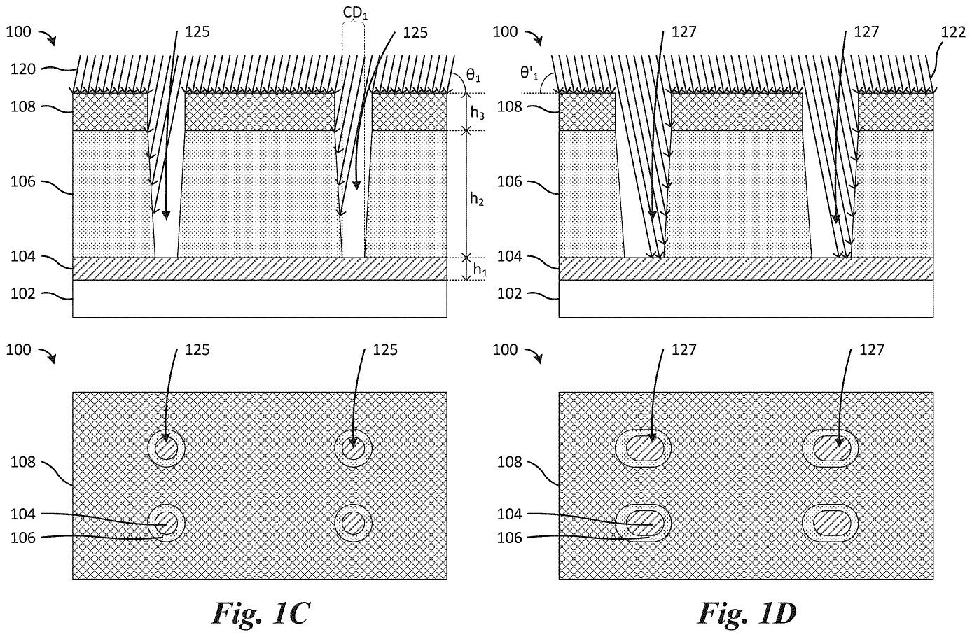

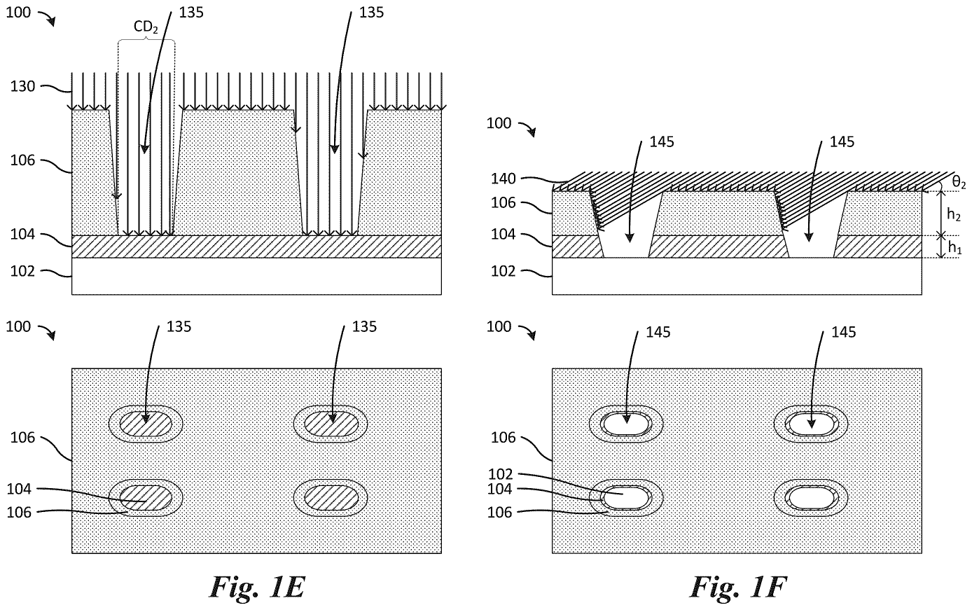

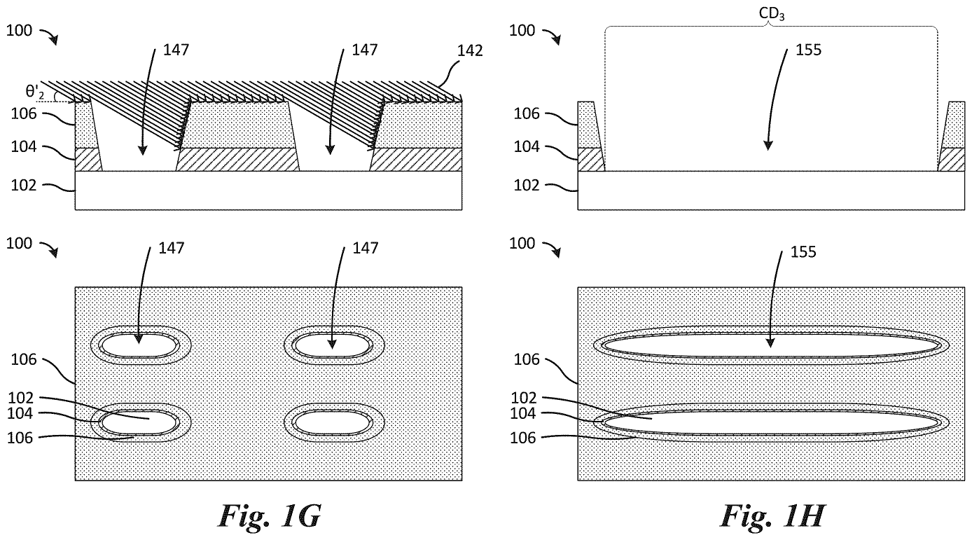

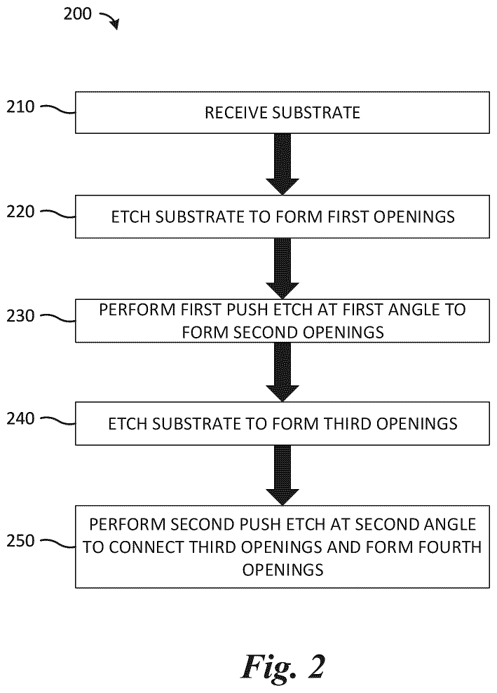

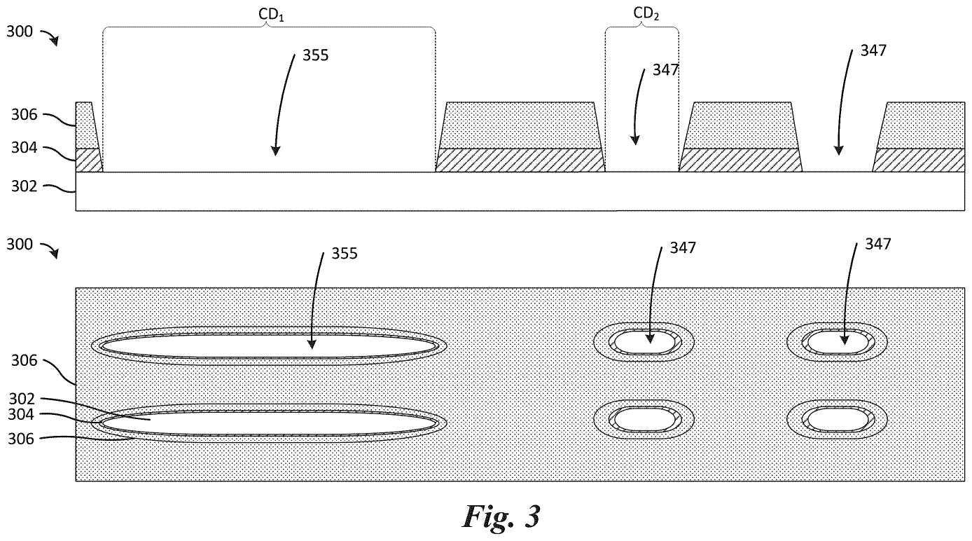

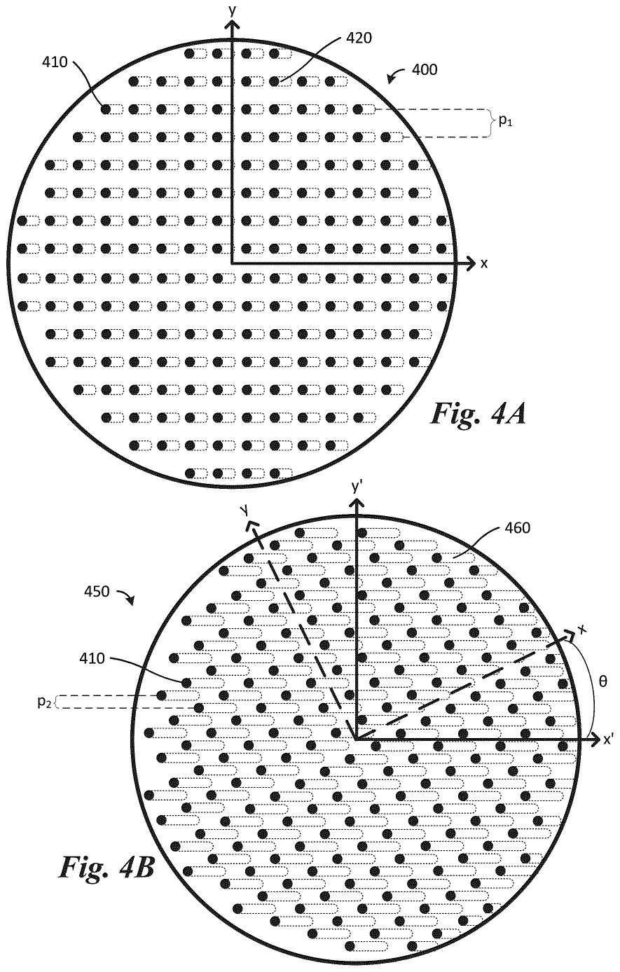

Embodiments provided below describe various methods, apparatuses and systems for processing a substrate, and in particular, to methods, apparatuses, and systems that use a focused beam at a processing angle to modify features in the substrate. The following description describes the embodiments. FIGS. 1A-1H describe an example processing method for modifying a feature pattern in a substrate using an angled focused beam. FIG. 2 is a flowchart used to describe the method of processing a substrate using an angled focused beam to modify features of this disclosure. FIG. 3 is used to describe an embodiment of the method of processing a substrate of FIGS. 1A-1H where the angled focused beam uses multiple processing angles to connect adjacent openings while extending critical dimensions of other openings without connecting. FIGS. 4A-4B are used to describe how the method of modifying features of this disclosure may be used to improve pattern pitch.

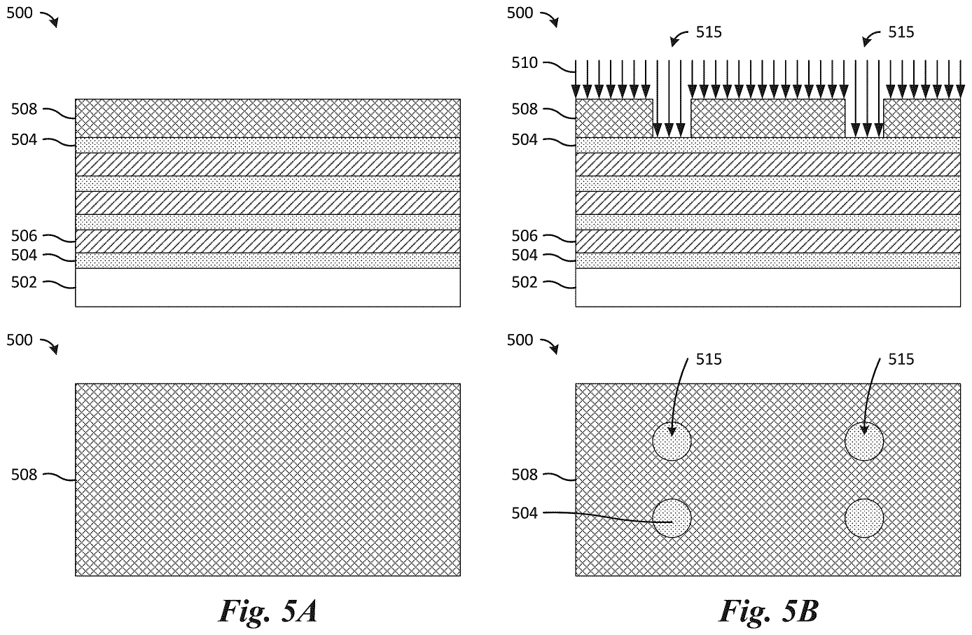

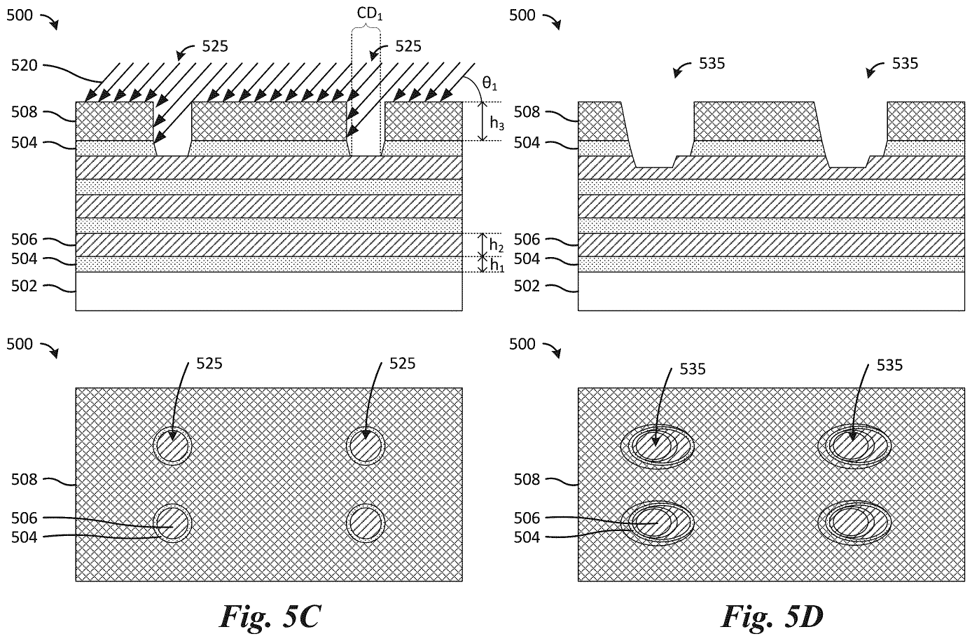

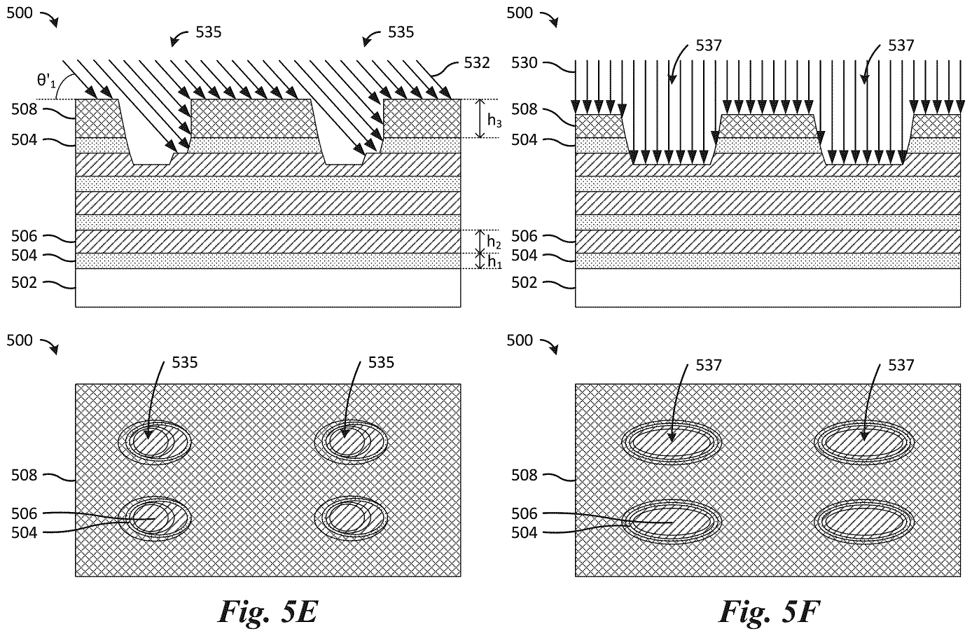

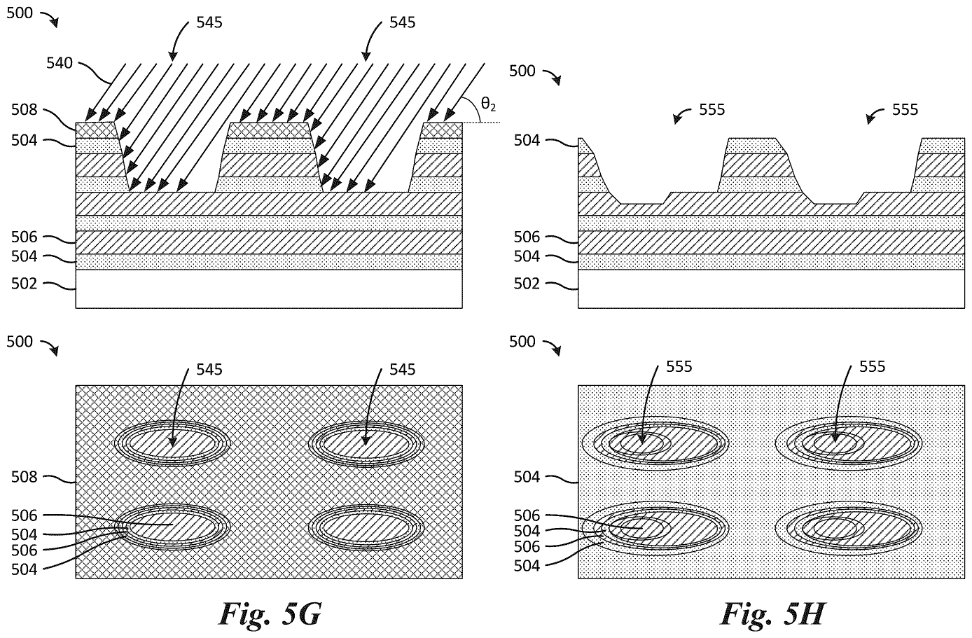

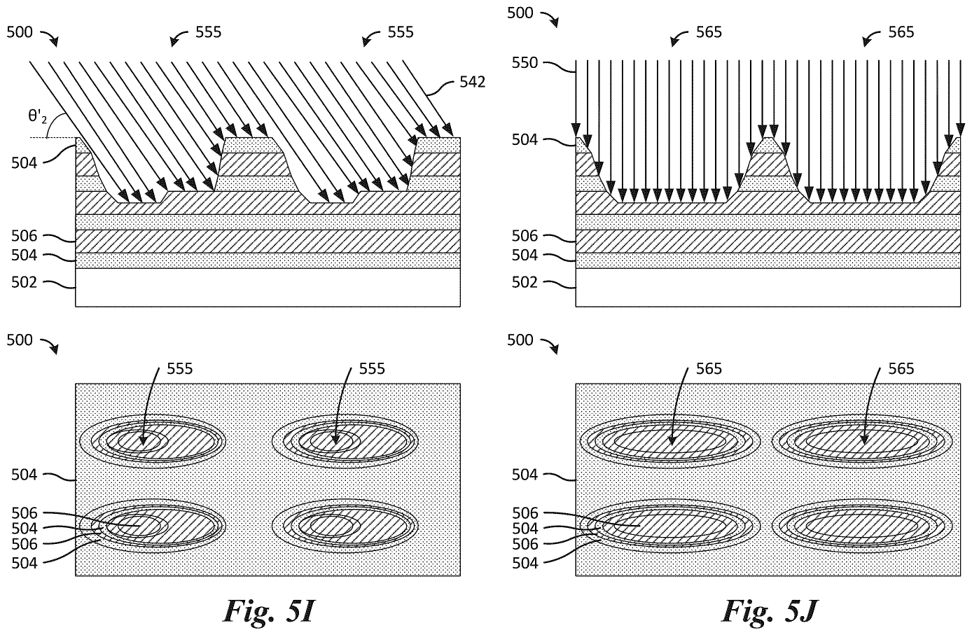

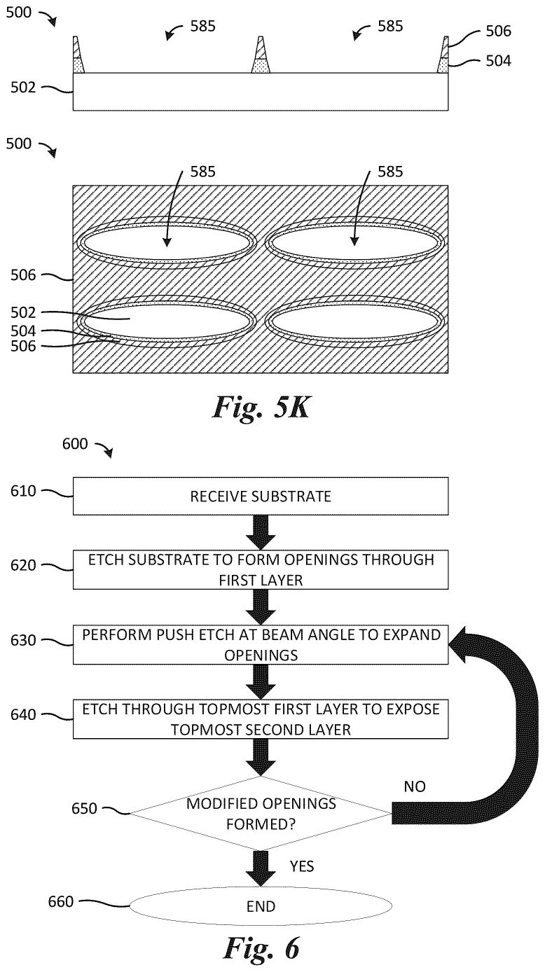

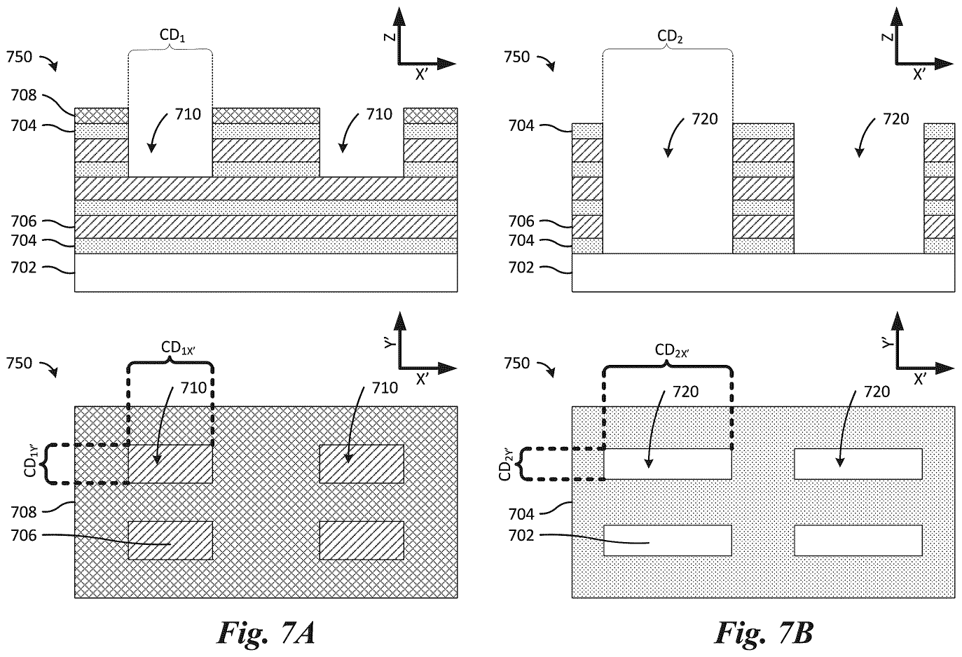

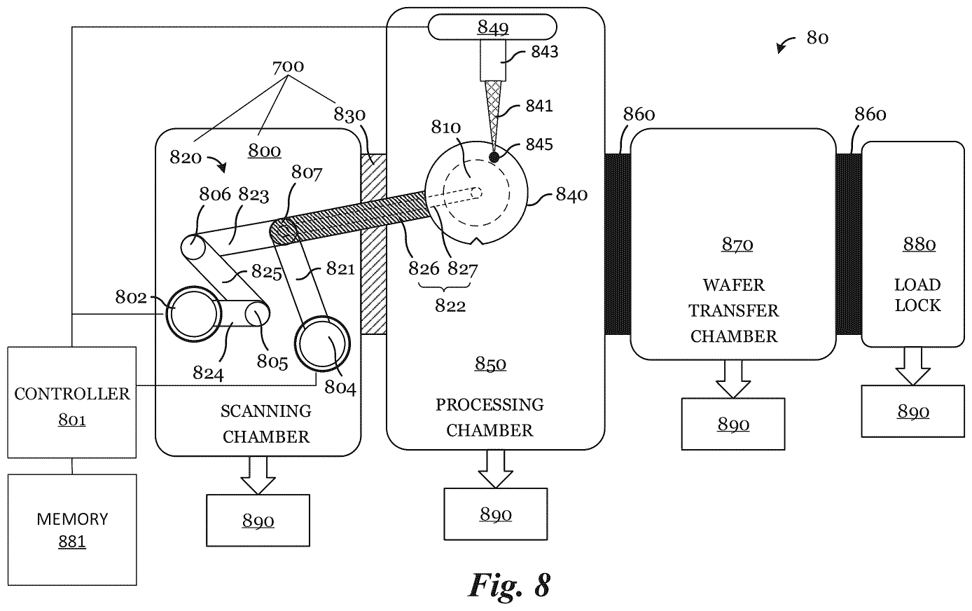

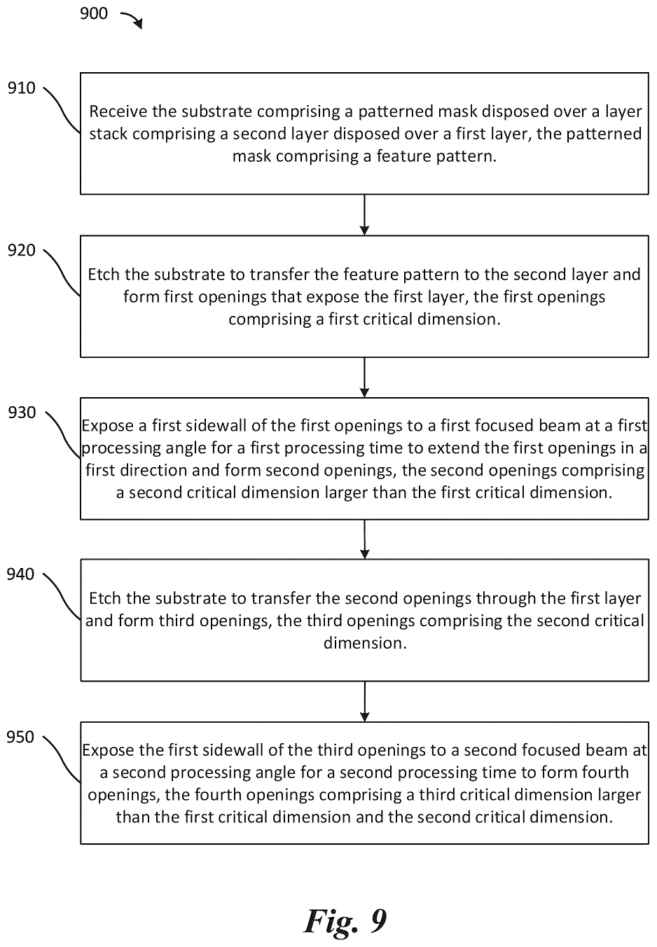

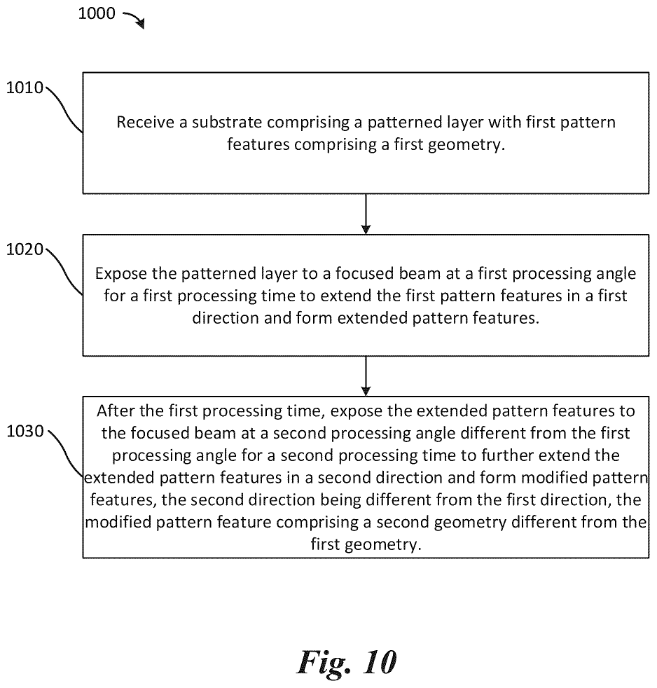

FIGS. 5A-5K are used to describe another example processing method for modifying a feature pattern in a substrate using an angled focused beam when the substrate comprises many alternating layers. FIG. 6 is a flowchart used to describe the method of processing a substrate using an angled focused beam to modify features of this disclosure. FIGS. 7A-7B are used to illustrate changes in critical dimensions of features on a substrate at different steps of an embodiment of the method of processing a substrate of FIGS. 5A-5K. An example processing system capable of implementing the processing method of this disclosure is described using FIG. 8. And the flowcharts of FIGS. 9-10 illustrate two other example processing methods that use an angled focused beam to modify features on a substrate in accordance with embodiments of this disclosure.

FIGS. 1A-1H each illustrate a cross-sectional side view and a top view of a substrate 100 during steps of a method for performing a critical dimension (CD) modification process in accordance with embodiments of this disclosure.

FIG. 1A illustrates the substrate 100 as received to be used in the CD modification process according to embodiments of this disclosure. The substrate 100 comprises a substrate base 102 with multiple material layers disposed thereon to form a layer stack suitable for pattern modification operations. A first layer 104 is disposed over the substrate base 102, and a second layer 106 is disposed over the first layer 104, where the layer stack comprises the first layer 104 and the second layer 106. A third layer 108 is disposed over the second layer 106 as the topmost layer of the substrate 100.

In various embodiments, the substrate base 102 may comprise silicon, silicon-on-insulator, or other semiconductor materials commonly used in integrated circuit fabrication. The substrate base 102 provides the foundational structure upon which the subsequent layers are formed and processed. The first layer 104 may have been deposited over the substrate base 102 through a suitable deposition process, such as chemical vapor deposition (CVD), plasma-enhanced CVD (PECVD), atomic layer deposition (ALD), or others. Similarly, the second layer 106 may have been deposited over the first layer 104 through another suitable deposition process, such as those listed for the first layer 104. In various embodiments, the third layer 108 may have been formed over the second layer 106 through a suitable deposition process for the material of the third layer 108. For example, in an embodiment where the third layer 108 comprises photoresist, a spin-on deposition process may have been used to form the third layer 108 over the second layer 106.

The first layer 104 may comprise an inorganic material such as silicon oxide, silicon nitride, or other dielectric materials. In one or more embodiments, the first layer 104 may be an intermediate processing layer. The thickness of the first layer 104 may be specified based on a desired etch selectivity and a desired pattern to be formed in the substrate 100.

The second layer 106 may comprise an organic material such as a carbon-based film, organic polymer, or other carbon-containing material. In various embodiments, the second layer 106 may comprise a suitable organic material that provides etch selectivity relative to the first layer 104. In those embodiments, the organic composition of the second layer 106 enables selective processing using oxygen-based gas cluster beams while maintaining resistance to other etch chemistries. Further, the thickness of the second layer 106 may also be specified based on a desired etch selectivity and a desired pattern to be formed in the substrate 100.

The third layer 108 may be used as an etch mask in subsequent processing steps. In those embodiments, the third layer 108 may comprise another inorganic material, a photoresist material, or a metal layer such as titanium nitride, tungsten, or other hard mask materials that serve as a protective layer during initial processing steps. And similarly, the thickness of the third layer 108 may also be specified based on a desired etch selectivity and a desired pattern to be formed in the substrate 100, where the third layer 108 may be used as a patterned mask.

The multi-layer configuration of the substrate 100 enables selective processing where different beam chemistries can preferentially etch certain layers while providing selectivity to others. In various embodiments, the layer thicknesses and compositions are selected to optimize the CD modification process and achieve the desired pattern transformation results. The substrate 100 represents the starting point for the CD modification operations that will be performed in subsequent processing steps.

After receiving the substrate 100, a patterning process is performed to form a feature pattern in the third layer 108 of the substrate 100. The third layer 108 may then be a patterned mask which may be used as an etch mask in subsequent processing steps. In various embodiments, the patterning process used to form the feature pattern comprising an initial geometry to be modified according to the CD modification process of this disclosure may be any suitable conventional patterning process. For example, the patterning process may use conventional lithographic and etching techniques to establish the initial pattern geometry in the third layer 108 for subsequent CD modification operations.

FIG. 1B illustrates the substrate 100 during an etch process 110 to transfer a feature pattern 115 of the third layer 108 to the second layer 106 after performing a patterning process to form the feature pattern 115 in the third layer 108 according to embodiments of the disclosure. The patterning process formed the feature pattern 115 that comprises features desired to be transferred through the second layer 106. For example, the patterning process formed a patterned mask as the third layer 108, which may be used to transfer the feature pattern 115 to the second layer 106 using the etch process 110.

In various embodiments, the feature pattern 115 may have been formed using a photolithographic process where the third layer 108 is a photoresist layer which may have been exposed to actinic radiation through a mask pattern and developed to create the desired feature pattern 115. In those embodiments, the exposed portions of the third layer 108 are then removed using an anisotropic etching process such as reactive ion etching or other directional etch techniques.

In various embodiments, the feature pattern 115 comprises sidewalls that are substantially vertical or slightly tapered depending on the patterning process. For example, FIG. 1B illustrates an embodiment where the feature pattern 115 comprises a circular shape, where a first sidewall and a second sidewall of an opening of the feature pattern 115 are oppositely disposed. In other embodiments, the first sidewall and the second sidewall are different sidewalls of the feature pattern 115. The feature pattern 115 defines the initial geometry (or a first geometry) of the openings and influence the subsequent directional processing steps. In one or more embodiments, the feature pattern 115 may comprise first openings of various shapes, such as square, circular, rectangular, or other polygonal shapes. In various embodiments, the starting features of the feature pattern 115 may comprise vias, contact holes, channel holes, pillars, mandrels, or combinations therein. The spacing and dimensions of the features in the feature pattern 115 may be selected based on a target pattern pitch or a target feature shape. After patterning the third layer 108 with the feature pattern 115 through the patterning process the etch process 110 is performed to transfer the feature pattern 115 to the second layer 106 and form first openings.

The etch process 110 may be selective to the third layer 108 while exhibiting controlled etch rates for the second layer 106 to achieve the desired opening depth and profile characteristics to transfer the feature pattern 115 to the second layer 106 and form first openings in the substrate 100. In various embodiments, the etch process 110 may comprise anisotropic etch processes or isotropic etch processes. For example, the etch process 110 may comprise a reactive ion etching (RIE) process, a deep reactive ion etching (DRIE) process, an atomic layer etching (ALE) process, a wet etching process, or combinations of multiple etching processes.

After transferring the feature pattern 115 to the second layer 106 using the etch process 110, the substrate 100 is ready for processing steps that will use a directional beam emitted at a first processing angle to modify the first geometry of the first openings.

FIG. 1C illustrates the substrate 100 during a first directional push etch 120 directed at a first sidewall of first openings 125 formed after performing the etch process 110 to transfer the feature pattern 115 to the second layer 106 according to embodiments of the disclosure. The first directional push etch 120 modifies the first openings 125 to form second openings that are modified as desired. In various embodiments, the first directional push etch 120 may be used to extend or lengthen the first openings 125 in a first direction. In other embodiments, the first directional push etch 120 may be used to extend first openings 125 towards an adjacent first opening. And in yet another embodiment, the first directional push etch 120 may be used to extend a plurality of the first openings 125 to merge the first openings 125 together.

In the embodiment illustrated in FIG. 1C, the first push etch 120 utilizes a first focused beam directed at the substrate 100 at a first processing angle θ₁ between a beam direction and a surface normal of a plane that is parallel to a surface of the substrate 100 to selectively remove material and expand the opening geometry of the first openings 125 as desired. The first processing angle θ₁ may range from approximately 15°to 85°depending on the desired extension characteristics and an aspect ratio of the first openings 125. For example, the first processing angle θ₁ may be determined using a first layer thickness h₁, a second layer thickness h₂, a third layer thickness h₃, and a first critical dimension CD₁ of the first openings 125 along with an associated etch rate of the second layer 106 by the first focused beam to avoid penetrating the first layer 104 during the first push etch 120. The directional nature of the first push etch 120 using a focused beam enables preferential material removal from one sidewall of each opening, resulting in asymmetric expansion that extends the first openings 125 in the first direction.

In one or more embodiments, the first push etch 120 selectively removes material from the second layer 106 while maintaining selectivity to the first layer 104 and other layers in the layer stack. In embodiments where the second layer 106 comprises organic materials, the first focused beam may comprise oxygen-based species. And in embodiments where the second layer 106 comprises inorganic materials, the first focused beam may comprise fluorine-based species.

In various embodiments, the first push etch 120 may be implemented according to a set of processing parameters comprising beam energy, and processing time, where all may be controlled to achieve the desired extension distance and sidewall profile characteristic modifications in the first openings 125. For example, the first push etch 120 may expose a first sidewall of the first openings 125 to a first focused beam for a first processing time at a first beam energy while the substrate 100 is maintained at a first substrate temperature. In some embodiments, the first push etch 120 exposes the substrate 100 to the focused beam which is scanned over the surface of the substrate 100 at the first processing angle θ₁ in a raster pattern or some other pattern as desired.

The first push etch 120 forms modified first openings which represent an intermediate stage in the CD modification process where the initial circular first openings 125 are transformed into elongated or extended features. The directional extension provided by the first push etch 120 establishes the foundation for subsequent processing steps that will further modify the pattern geometry.

FIG. 1D illustrates the substrate 100 during a modified first push etch 122 to form second openings from modified first openings 127, where the modified first openings 127 were formed after performing the first push etch 120 according to embodiments of this disclosure. As illustrated in the top view of the substrate 100, the modified first openings 127 were extended in a first direction according to the first push etch 120. Using the modified first push etch 122, which scans the surface of the substrate 100 with a modified first focused beam at a modified first processing angle θ′₁ directed at second sidewalls of the modified first openings 127, the modified first openings 127 may be further extended (or symmetrically extended) in a second direction opposite the first direction to form second openings.

In various embodiments, the modified first processing angle θ′₁ may be oriented in an opposing direction relative to the first direction of the first processing angle θ₁ to create bidirectional extension of the first openings 125. The combination of the first push etch 120 and the modified first push etch 122 may be a bidirectional push etch that symmetrically modifies the first openings 125 to form second openings as desired. In one or more embodiments, the modified first push etch 122 uses the first focused beam at the modified first processing angle θ′₁, which is directed at the same angle as the first processing angle θ₁, but in an opposite direction (a second direction) of the first openings 125 (such as rotated 180°).

The openings formed using the bidirectional push etch approach illustrated in FIG. 1D may exhibit sidewall profiles that reflect the bidirectional nature of the push etch process. The symmetric expansion of the bidirectional push etch approach provides more uniform opening dimensions and improved pattern fidelity compared to unidirectional processing. The first bidirectional push etch (combinations of 120 and 122) selectively removes material from the second layer 106 on both sides of each opening while maintaining selectivity to the first layer 104 and other layers in the stack. In various embodiments, the modified first push etch 122 may use the modified first focused beam comprising similar beam chemistries as the first focused beam of the first push etch 120 described above.

FIG. 1E illustrates the substrate 100 during an etch process 130 to transfer second openings 135 through the first layer 104 to expose the substrate base 102, where the second openings 135 were formed after performing the first push etch 120 and the modified first push etch 122 according to embodiments of the disclosure. The etch process 130 extends the second openings 135 downward to form third openings that penetrate through the remaining thickness of the first layer 104. In various embodiments, the etch process 130 may also be used to remove remaining material or residual material left over in the second openings 135 from the first push etch 120 and the modified first push etch 122. In some embodiments, the etch process 130 may also be used to remove any remaining material of the third layer 108 to fully expose the second layer 106.

The etch process 130 may comprise an anisotropic etching technique such as reactive ion etching or plasma etching that provides directional etch characteristics. The etch chemistry is selected to effectively remove the material of the first layer 104 while maintaining the sidewall profiles established in the previous processing steps and a critical dimension (CD₂) of the second openings 135. The etch process 130 exhibits controlled selectivity between the first layer 104 and the substrate base 102 to achieve precise etch depth control and avoid substrate damage.

The etch process 130 may be used to form third openings that maintain the expanded geometry (the critical dimension (CD₂)) created by the first push etch 120 and the modified first push etch 122 while extending the pattern through the full thickness of the layer stack.

In various embodiments, parameters of the etch process 130 may comprise etch time, plasma power, and gas flow rates optimized to achieve complete pattern transfer while maintaining the desired sidewall profile characteristics. The third openings represent a significant stage in the CD modification process where the directionally extended pattern has been successfully transferred through the layer stack of the substrate 100. After forming the third openings using the etch process 130, the substrate 100 is prepared for additional directional processing steps that may further modify the pattern geometry or connect adjacent features.

FIG. 1F illustrates the substrate 100 undergoing a second push etch 140 at a second processing angle θ₂ after performing the etch process 130 to form third openings 145 comprising the second critical dimension CD₂ according to embodiments of the disclosure. The second push etch 140 extends the third openings 145 to form modified third openings that are further enlarged in the first direction. In various embodiments, the second push etch 140 utilizes a second focused beam directed at the substrate 100 at the second processing angle θ₂ to selectively remove additional material from the first sidewall of the third openings 145 and expand the opening geometry beyond the second critical dimension CD₂ formed from the first push etch 120 and the modified first push etch 122.

The second focused beam is incident on the substrate 100 at the second processing angle θ₂ relative to a surface normal of a plane parallel to the surface of the substrate 100. The second processing angle θ₂ may be different from the first processing angle θ₁ and may vary between 15° and 85° based on the desired extension characteristics and pattern specifications of the features being formed in the substrate 100. In various embodiments, the second processing angle θ₂ may be oriented in the same general direction as the first direction of the first processing angle θ₁ to achieve enhanced unidirectional extension.

The second push etch 140 continues to selectively remove material from the remaining portions of the second layer 106 and potentially the first layer 104 while maintaining selectivity to the substrate base 102. In one or more embodiments, the beam chemistry and processing parameters for the second push etch 140 may be similar to or different from the first push etch 120 depending on the target materials and desired etch characteristics. The enhanced opening dimensions achieved through the second push etch 140 facilitate the subsequent pattern connection steps that may transform the discrete openings (third openings 145) into continuous line features in some embodiments.

FIG. 1G illustrates the substrate 100 during a modified second push etch 142 to form fourth openings from modified third openings 147, where the modified third openings 147 were formed after performing the second push etch 140 according to embodiments of this disclosure. As illustrated in the top view of the substrate 100, the modified third openings 147 were extended in a first direction according to the second push etch 140. Using the modified second push etch 142, which scans the surface of the substrate 100 to a modified second focused beam at a modified second processing angle θ′₂ along second sidewalls of the modified third openings 147, the modified third openings 147 may be further extended (or symmetrically extended) in a second direction opposite the first direction to form fourth openings.

In various embodiments, the modified second processing angle θ′₂ may be oriented in an opposing direction relative to the first direction of the second processing angle θ₂ to create bidirectional extension of the third openings 145. The combination of the second push etch 140 and the modified second push etch 142 may be a bidirectional push etch that symmetrically modifies the third openings 145 to form fourth openings as desired. In one or more embodiments, the modified second push etch 142 uses the second focused beam at the modified second processing angle θ′₂, which is directed at the same angle as the second processing angle θ₂, but in an opposite direction (a second direction) of the third openings 145 (such as rotated 180°).

The openings formed using the bidirectional push etch approach illustrated in FIG. 1G may exhibit sidewall profiles that reflect the bidirectional nature of the push etch process.

The symmetric expansion of the bidirectional push etch approach provides more uniform opening dimensions and improved pattern fidelity compared to unidirectional processing. The second bidirectional push etch (combinations of 140 and 142) selectively removes material from the first layer 104 and the second layer 106 on both sides of each opening while maintaining selectivity to the substrate base 102 and other layers in the stack. In various embodiments, the modified second push etch 142 may use the modified second focused beam comprising similar beam chemistries as the second focused beam of the second push etch 140 described above.

FIG. 1H illustrates the substrate 100 after completing the CD modification process to form fourth openings 155 comprising a third critical dimension CD₃ according to embodiments of the disclosure. The sequential directional push etch operations have successfully transformed the initial discrete openings into interconnected trench features that span across the substrate 100. The fourth openings 155 represent the final pattern geometry achieved through the multi-step CD modification process, demonstrating significant pitch reduction compared to the original opening pattern.

The fourth openings 155 are formed by the connection and merging of the third openings 145 from the previous processing steps. The directional extensions created by the sequential push etch operations at different processing angles have caused adjacent openings to expand sufficiently to connect with one another, forming continuous linear features. The fourth openings 155 extend through the multi-layer stack and expose the underlying substrate base 102 along their entire length, providing complete pattern transfer through the film stack. For example, in an embodiment, the fourth openings 155 may be trenches formed in the substrate 100.

The sidewall profiles of the fourth openings 155 reflect the cumulative effects of the multiple directional processing steps performed during the CD modification sequence. The opening geometry exhibits characteristics that would be challenging to achieve through conventional single-step lithographic processes. The width and spacing of the fourth openings 155 may also demonstrate the pitch reduction capability of the CD modification approach, where the final pattern pitch is smaller than the initial opening pitch of the first openings 125.

In various embodiments, the fourth openings 155 may be used for subsequent device fabrication steps such as metal deposition, dielectric filling, or other semiconductor processing operations. The CD modification process enables the creation of high-density line-space patterns that exceed the resolution limits of conventional lithographic techniques. The substrate 100 with the formed fourth openings 155 represents the successful completion of the pattern transformation process, where discrete contact holes have been converted into continuous line features with reduced pitch and enhanced pattern density in the embodiment illustrated in FIGS. 1A-1H.

FIG. 2 illustrates a flowchart of a method 200 for performing a CD modification process according to embodiments of the disclosure. The method 200 provides an approach for transforming or modifying discrete pattern features from a first geometry to a second geometry as desired through sequential directional processing operations. In various embodiments, the method 200 may be the CD modification process described using FIGS. 1A-1H, where initial openings are modified using a directional beam process.

The method 200 begins at step 210 with receiving a substrate to be used in a CD modification process. In various embodiments, the substrate may comprise a multi-layer stack suitable for CD modification operations. The substrate may comprise multiple material layers with different etch characteristics to enable controlled pattern modification during subsequent processing steps. Additionally, the substrate may comprise a patterned mask with a feature pattern to be transferred to underlying layers. In an embodiment, step 210 may be the step illustrated using FIG. 1B, where the substrate is the substrate 100.

Step 220 involves etching the substrate to form first openings in the topmost layer of the substrate according to the feature pattern of the patterned mask. The first openings are formed using conventional etching techniques to establish the initial pattern geometry (or first geometry) with predetermined spacing and dimensions. For example, the first openings may comprise first critical dimensions and a first pitch. In various embodiments, step 220 may be the step illustrated using FIG. 1B.

Step 230 comprises performing a first push etch at a first angle to form second openings with expanded geometry compared to the first openings. The first push etch utilizes directional beam processing to selectively remove material from one side of each opening, creating asymmetric extension in a first direction, such as along a first sidewall of the first openings. In various embodiments, the first push etch may be the first push etch 120, the first angle may be the first processing angle θ₁, and the first openings may be the first openings 125 of FIG. 1C, and step 230 may be the step illustrated and described using FIG. 1C. In an embodiment, step 230 may be a bidirectional push etch approach where step 230 may be both the first push etch 120 of FIG. 1C and the modified first push etch 122 of FIG. 1D.

Step 240 involves etching the substrate to form third openings from the second openings formed in step 230 that extend the pattern through additional layers of the stack. The etching process transfers the expanded pattern geometry through the multi-layer stack while maintaining the directional characteristics established in the previous step. In various embodiments, step 240 may be the step described using FIG. 1E, where the etching the substrate to form third openings is the etch process 130 performed on the substrate 100 to form third openings from the second openings 135.

Step 250 comprises performing a second push etch at a second angle to connect the third openings and form fourth openings with further expanded geometry. The second push etch may be oriented in the same or different direction relative to the first push etch to achieve the desired pattern connection and pitch reduction. The sequential directional processing steps enable the transformation of discrete openings into continuous interconnected features, demonstrating the effectiveness of the CD modification approach for achieving enhanced pattern density and reduced pitch characteristics. In various embodiments, the second push etch may be the second push etch 140 performed on a first sidewall of the third openings 145 in FIG. 1F and the modified second push etch 142 performed on a second sidewall of the modified third openings 147 in FIG. 1G to form the fourth openings 155 of FIG. 1H. And in those embodiments, step 250 may be the steps described using FIGS. 1F-1H.

FIG. 3 illustrates a top view and a cross-sectional side view of a substrate 300 processed using the CD modification process in accordance with an embodiment of this disclosure. The substrate 300 comprises a substrate base 302, a first layer 304, a second layer 306, and a third layer 308, which may be as previously described for the substrate base 102, the first layer 104, the second layer 106, and the third layer 108 of the substrate 100. In the embodiment illustrated in FIG. 3, the CD modification process combined adjacent openings to form a combined opening 355 of a first critical dimension CD₁, while extending other openings 347 to a second critical dimension CD₂ without combining them. As a result, the CD modification process formed the combined opening 355 of a first critical dimension CD₁ and extended openings 347 of a second critical dimension CD₂. In various embodiments, this may result from the feature pattern modified using the CD modification process comprising openings non-uniformly distributed. Thus, only openings disposed within a modification distance are combined, while others do not combine, but are extended similarly. In other words, the CD modification process of this disclosure may be used to form multiple openings of different critical dimensions and shapes through a directional push etch process.

FIGS. 4A-4B illustrate the ability of the CD modification process of this disclosure to form features with smaller pitches than conventional methods. The figures demonstrate the pitch reduction capability achieved through the sequential directional processing approach, where the final pattern pitch may be reduced compared to a first pitch of the initial openings.

FIG. 4A shows a first pattern configuration 400 on a substrate with first openings 410 arranged in a regular array with an initial pitch p₁. The first openings 410 are positioned along both x and y coordinate axes with uniform spacing that represents the starting pattern geometry before CD modification operations. The initial pitch p₁ corresponds to the center-to-center distance between adjacent openings and defines the pattern density achievable through conventional lithographic techniques. In an embodiment, the CD modification process of this disclosure may be used to form modified openings 420 that comprise the same initial pitch p₁ as the first openings 410.

The first openings 410 may be formed using standard photolithographic processes with resolution limits that constrain the minimum achievable pitch. The modified openings 420 represent the minimum feature separation that can be reliably manufactured using conventional patterning approaches that use the CD modification approach of this disclosure to form the modified openings 420 without modifying the initial pitch p₁. The first pattern configuration 400 serves as the baseline for comparison with the enhanced pattern density which may be achieved through the CD modification method of this disclosure.

FIG. 4B illustrates a second pattern configuration 450 after completing the CD modification process to change the pitch of the first openings 410, where the first openings 410 have been extended and connected to form continuous trenches 460. The trenches 460 are oriented along the x′ and y′ coordinate axes with a final pitch p₂ that is smaller than the initial pitch p₁. The directional processing operations have successfully transformed the discrete opening pattern into a continuous line-space pattern with enhanced density characteristics by extending the first openings 410 along a different direction than the first pattern configuration 450. For example, as illustrated in FIG. 1B, the trenches 460 may be formed by performing directional push etches along the x′ coordinate axis, which is rotated a tilt angle θ from the x coordinate axis the modified openings 420 were pushed along in FIG. 4A.

A pitch reduction ratio p₂/p₁ demonstrates the effectiveness of the CD modification approach in achieving pattern densities that exceed conventional lithographic capabilities. In various embodiments, the CD modification process can achieve pitch reductions between 50% and 100%, which may effectively double the pattern density compared to the initial configuration. The trenches 460 exhibit uniform spacing and dimensions across the substrate, demonstrating the process control and repeatability of the CD modification technique. The enhanced pattern density enables the fabrication of advanced semiconductor devices with improved performance characteristics and pitch control.

FIGS. 5A-5K each illustrate a cross-sectional side view and a top view of a substrate 500 during steps of a method for performing a CD modification process in accordance with embodiments of this disclosure.

FIG. 5A illustrates the substrate 500 which may be used in the CD modification process according to embodiments of the disclosure. The substrate 500 comprises a substrate base 502 with multiple material layers disposed thereon to form a layer stack suitable for pattern transformation operations. A first layer 504 is disposed over the substrate base 502, followed by a second layer 506 disposed over the first layer 504. In various embodiments, as many first layers 504 and second layers 506 may be formed alternating as desired to form the layer stack disposed over the substrate base 502. A third layer 508 is disposed over the topmost layer of the layer stack.

The substrate base 502 may comprise silicon, silicon-on-insulator, or other semiconductor materials commonly used in integrated circuit fabrication. The first layer 504 may comprise an inorganic material such as silicon oxide, silicon nitride, or other dielectric materials that serve as an etch stop or intermediate processing layer. The second layer 506 may comprise an organic material such as a carbon-based film, organic polymer, or other carbon-containing material that provides etch selectivity relative to the inorganic layers. The third layer 508 may comprise another inorganic material or a metal layer such as titanium nitride, tungsten, or other hard mask materials. The various layers may have been formed through conventional deposition methods as previously described for the layers of the substrate 100 in FIGS. 1A-1H.

The multi-layer configuration of the substrate 500 enables selective processing where different beam chemistries can preferentially etch certain layers while providing selectivity to others. The layer thicknesses and compositions are selected to optimize the CD modification process and achieve the desired pattern transformation results. The substrate 500 represents the starting point for the CD modification operations that may transform discrete pattern features into continuous interconnected structures in some embodiments. For example, the substrate 500 may be patterned through a suitable patterning process to form a feature pattern in the third layer 508.

FIG. 5B illustrates the substrate 500 during an etch process 510 to transfer a feature pattern 515 through the topmost first layer 504 after performing a patterning process to form the feature pattern 515 in the third layer 508 according to embodiments of the disclosure. The third layer 508 comprising the feature pattern 515 may be used as a patterned mask or an etch mask during the etch process 510. The etch process 510 forms first openings through the topmost first layer 504 to expose the topmost second layer 506 of the layer stack. The feature pattern 515 may be formed using conventional lithographic and patterning techniques to establish the initial pattern geometry for subsequent CD modification operations, such as described for the feature pattern 115 of FIG. 1B. In various embodiments, the etch process 510 may be as described for the etch process 110 of FIG. 1B.

FIG. 5C illustrates the substrate 500 during a first push etch 520 at a first processing angle θ₁ to extend first openings 525 in a first direction after performing the etch process 510 to form the first openings 525 according to embodiments of the disclosure. The directional push etch extends the openings 510 to form expanded openings that are enlarged in a first direction.

The push etch operation utilizes a first focused beam directed at the substrate 500 at the first processing angle θ₁ to selectively remove material and expand the opening geometry through directional processing. In various embodiments, the first processing angle θ₁ may be specified based on a material removal rate, a first layer thickness h₁, a second layer thickness h₂, a third layer thickness h₃, and a first critical dimension CD₁ of the first openings 525.

In contrast to the method described using FIGS. 1A-1H, the method described using FIGS. 5A-5K may be performed similarly, but for more push etches, more processing angles, and for more layers in the layer stack on the substrate 500. Consequently, the push etches may be specified based on the number of layers of the layer stack, the amount of material to be removed by accounting for the material removal rate, the processing timeframe, and the opening geometry (such as opening depth). The various push etches may be as similarly described for the push etches of FIGS. 1A-1H, but for more etches. Similarly, the etch processes of FIGS. 5A-5K may be as described for the etch processes of FIGS. 1A-1H, but the etch processes of FIGS. 5A-5K may be for removing excess material remaining in the openings to reveal a topmost layer to be etched in a subsequent push etch process to modify the opening geometry.

As illustrated in FIG. 5C, the first push etch 520 exposes the substrate 500 to a first processing beam at the first processing angle θ₁ relative to a planar surface of the substrate 500. The first processing angle θ₁ may range from approximately 15° to 85° depending on the desired extension characteristics and the aspect ratio of the first openings 525. The directional nature of the beam processing causes preferential material removal from one side of each first opening 525, resulting in asymmetric expansion that extends the first openings 525 in the first direction on the first sidewalls.

In various embodiments, push etch parameters (or processing parameters) of the first push etch 520 comprise beam energy, and processing time which may be controlled to achieve the desired extension distance and sidewall profile characteristics on the first openings 525. The modification of the first openings 525 represents an intermediate stage in the CD modification process where the initial circular or rectangular openings are transformed into elongated features that will facilitate subsequent pattern connection or modification operations.

FIG. 5D illustrates the substrate 500 after performing the first push etch 520 to form modified first openings 535 which were expanded along a first direction by exposing the first sidewalls of the first openings 525 to the first focused beam.

FIG. 5E illustrates the substrate 500 during a modified first push etch 532 on second sidewalls of the modified first openings 535 to expand the modified first openings 535 in a second direction in accordance with embodiments of this disclosure. In the embodiment illustrated in FIG. 5E, the second sidewalls are disposed opposite the first sidewalls, and the modified first push etch 532 exposes the second sidewalls to a modified first focused beam at a modified first processing angle θ′₁ which may have been determined based on the layer thicknesses as described for the first processing angle θ₁ above. In various embodiments, the modified first focused beam may be as similarly described for the first focused beam used in the first push etch 520 described above, and the modified first processing angle θ′₁ may be the same as the first processing angle θ₁ but rotated 180°to expose the second sidewall in a second direction. In other embodiments, the modified first processing angle θ′₁ may be different than the first processing angle θ₁, but may vary between 15° and 85°.

In various embodiments, the modified first processing angle θ′₁ may be oriented in an opposing direction relative to the first direction of the first processing angle θ₁ to create bidirectional extension of the first openings 525. The combination of the first push etch 520 and the modified first push etch 532 may be a bidirectional push etch that symmetrically modifies the first openings 525 to form second openings as desired. In one or more embodiments, the modified first push etch 532 uses the first focused beam at the modified first processing angle θ′₁, which is directed at the same angle as the first processing angle θ₁, but in an opposite direction (a second direction) of the first openings 525 (such as rotated 180°).

The openings formed using the bidirectional push etch approach illustrated in FIG. 5E may exhibit sidewall profiles that reflect the bidirectional nature of the push etch process. The symmetric expansion of the bidirectional push etch approach provides more uniform opening dimensions and improved pattern fidelity compared to unidirectional processing. The first bidirectional push etch (combinations of 520 and 532) selectively removes material from the second layer 506 on both sides of each opening while maintaining selectivity to the first layer 504 and other layers in the stack. In various embodiments, the modified first push etch 532 may use the modified first focused beam comprising similar beam chemistries as the first focused beam of the first push etch 520 described above.

In some embodiments, the bidirectional push etch may form openings that comprise critical dimensions that have been increased in one direction, but decreased in an orthogonal direction. For example, the critical dimension of the second openings may comprise an increased critical dimension along the first and second directions of the focused beams, but a decreased critical dimension in a direction orthogonal to the first and second directions. This possibility is further described below using FIGS. 7A-7B.

FIG. 5F illustrates the substrate 500 during an etch process 530 to remove residual material in expanded first openings 537 and push through the topmost first layer 504 after performing the first push etch 520 to extend the first openings 525 in the first direction and second direction and form second openings according to embodiments of the disclosure. The etch process 530 extends the expanded first openings 537 downward to form second openings that penetrate through the remaining thickness of the overlying layers while removing residual material from the first push etch 520. As illustrated, the expanded first openings 537 have a larger critical dimension than the first openings 525 of FIG. 5C due to the first bidirectional push etch (comprising the first push etch 520 and the modified first push etch 532) expanding the first openings 525 along the first sidewalls and second sidewalls.

In various embodiments, the etch process 530 may be as previously described for the etch processes of the method described using FIGS. 1A-1H. For example, the etch process 530 may be a combination of two selective etch steps, such as a first etch step selective to the material of the topmost second layer 506 to remove residue and reveal the topmost first layer 504, and a second etch step which selectively etches the material of the topmost first layer 504 to expose the second layer 506 beneath for further directional push etches. Similarly, the processing parameters of the etch process 530 may comprise processing times, gas flow rates, substrate temperatures, etchant composition, and plasma power.

The subsequent processing steps perform a similar process, where a bidirectional push etch is performed after an etch process to further modify or expand openings as may be desired. Throughout the CD modification process, the processing angles may vary based on the aspect ratio of the openings, the material removal rates, the material composition of the various layers to be processed, and the desired feature pattern to be achieved through the pattern modification. As a result, the subsequent processing steps may be as previously described, but for modified processing angles based on the aspect ratios of the openings formed.

FIG. 5G illustrates the substrate 500 during a second push etch 540 at a second processing angle θ₂ to extend second openings 545 after performing the etch process 530 to form the second openings 545 according to embodiments of the disclosure. The second push etch 540 exposes the first sidewalls of the second openings 545 to a focused beam to remove material from the first sidewall and expand the second openings 545 along the first direction. The second push etch 540 may be as previously described above for the first push etch 520, but at a second processing angle θ₂ which may vary between 15° and 85° as desired for modifying the second openings 545.

FIG. 5H illustrates the substrate 500 after performing the second push etch 540 to form modified second openings 555 which were expanded along a first direction by exposing the first sidewalls of the second openings 545 to the second focused beam.

FIG. 5I illustrates the substrate 500 during a modified second push etch 542 on second sidewalls of the modified second openings 555 to expand the modified second openings 555 in a second direction in accordance with embodiments of this disclosure. In the embodiment illustrated in FIG. 5I, the second sidewalls are disposed opposite the first sidewalls, and the modified second push etch 542 exposes the second sidewalls to a modified second focused beam at a modified second processing angle θ′₂ which may have been determined based on the layer thicknesses as described for the first processing angle θ₁ above. In various embodiments, the modified second focused beam may be as similarly described for the second focused beam used in the second push etch 540 described above, and the modified second processing angle θ′₂ may be the same as the second processing angle θ₂ but rotated 180° to expose the second sidewall in a second direction. In other embodiments, the modified second processing angle θ′₂ may be different than the second processing angle θ₂, but may vary between 15° and 85°.

In various embodiments, the modified second processing angle θ′₂ may be oriented in an opposing direction relative to the first direction of the second processing angle θ₂ to create bidirectional extension of the second openings 545. The combination of the second push etch 540 and the modified second push etch 542 may be a second bidirectional push etch that symmetrically modifies the second openings 545 to form third openings as desired. In one or more embodiments, the modified second push etch 542 uses the second focused beam at the modified second processing angle θ′₂, which is directed at the same angle as the second processing angle θ₂, but in an opposite direction (a second direction) of the second openings 545 (such as rotated 180°).

The openings formed using the second bidirectional push etch approach illustrated in FIG. 5I may exhibit sidewall profiles that reflect the bidirectional nature of the push etch process. The symmetric expansion of the bidirectional push etch approach provides more uniform opening dimensions and improved pattern fidelity compared to unidirectional processing. The second bidirectional push etch (combinations of 540 and 542) selectively removes material from the second layer 506 on both sides of each second opening 545 while maintaining selectivity to the first layer 504 and other layers in the stack. In various embodiments, the modified second push etch 542 may use the modified second focused beam comprising similar beam chemistries as the second focused beam of the second push etch 540 described above.

FIG. 5J illustrates the substrate 500 during an etch process 550 to remove residual material from expanded second openings 565 formed by the second bidirectional push etch according to embodiments of the disclosure. The etch process 550 may be as previously described for the other vertical etch processes above to extend the expanded second openings 565 through the topmost first layer 504 and expose a second layer 506 beneath for further directional push etches. The processing parameters of the etch process 550 may comprise similar elements as the processing parameters of other vertical etch process, but with different specifications, such as different exposure times. Additional bidirectional push etches may be performed as desired using different or similar processing angles within 15° and 85°. In some embodiments, as many bidirectional push etches may be performed as there are layers in the layer stack of the substrate 500.

FIG. 5K illustrates the substrate 500 after performing as many bidirectional push etches and as many vertical etches (etch processes) for forming modified openings as desired.

The substrate 500 comprises modified openings 585 of a final critical dimension larger than the first critical dimension CD₁ of the first openings 525. In some embodiments, the final etch process may remove any remaining material between adjacent openings to form continuous trenches to create well-defined trench features with optimized sidewall profiles and dimensional characteristics. The modified openings 585 represents the completed pattern transformation where the initial discrete openings have been successfully modified in critical dimension or other feature parameters as desired, such as forming trenches.

The modified openings 585 exhibits uniform width and spacing across the substrate 500, demonstrating the process control and repeatability achieved through the sequential directional processing approach. Though FIGS. 5A-5K illustrate a CD modification process that used two directional push etches on a first and second sidewall, other embodiments may utilize a unidirectional approach (where only a first sidewall is exposed during the push etches to expand or modify openings in a single direction) or additional push etches, or both to achieve a CD modification process to form modified openings 585 as desired.

The final processing step may comprise an additional anisotropic etch operation or cleaning process to remove any residual material and optimize the feature geometry of the modified openings 585. The processing parameters are selected to achieve the desired sidewall profile characteristics while maintaining the dimensional accuracy established through the previous directional processing steps. The modified openings 585 demonstrate the effectiveness of the CD modification approach in achieving pattern densities that exceed conventional lithographic capabilities.

FIG. 6 illustrates a flowchart of a method 600 for performing a CD modification process according to embodiments of the disclosure. The method 600 provides a systematic approach for transforming discrete pattern features as desired through sequential directional processing operations. In various embodiments, the method 600 may be the CD modification process described using FIGS. 5A-5K, where initial openings are progressively extended through multiple bidirectional push etch operations to form continuous patterns or modified openings.

The method 600 begins at step 610 with receiving a substrate having a multi-layer stack configuration suitable for CD modification operations. The substrate may comprise multiple material layers with different etch characteristics to enable controlled pattern modification during subsequent processing steps. In various embodiments, step 610 may be the step described using FIG. 5A or FIG. 1A. Step 620 etches the substrate to form openings through the first layer, creating discrete pattern features that serve as the starting geometry for the CD modification process. For example, an etch process may be performed to transfer a feature pattern to a topmost layer of the layer stack of the substrate, such as described using FIG. 5B and FIG. 1B.

Step 630 comprises performing a push etch at a beam angle to expand the openings in a controlled directional manner. The push etch utilizes focused beam processing with a specific incident angle (or beam angle) to selectively remove material from targeted regions (sidewalls) of each opening, creating asymmetric expansion that extends the openings in a predetermined direction as desired. In various embodiments, step 630 may be the step illustrated and described using FIG. 5C and FIG. 1C above. Further, in embodiments that use a bidirectional approach, a modified push etch may be performed at a modified processing (or beam) angle to expand the openings in a second direction opposite the first direction, such as described using FIG. 5E and FIG. 1D above. Step 640 etches through the topmost first layer to expose the topmost second layer of the multi-layer stack of the substrate, providing access to additional material layers for continued processing. As another example, step 640 may be the steps described using FIG. 5F and FIG. 1E above.

Step 650 comprises a decision point that checks whether modified openings have been formed as desired by the method 600. The evaluation may involve measuring the opening dimensions, spacing between adjacent openings, or other pattern characteristics to determine if the CD modification process has achieved the target geometry. If the answer is no, indicating that additional processing may be desired, the method 600 returns to step 630 to perform additional push etch operations at the same or different beam angles. This iterative approach allows for precise control over the pattern transformation through multiple sequential processing steps.

If the answer at step 650 is yes, indicating that the desired modified openings formation has been achieved, the method 600 proceeds to step 660 where the process ends. The completed CD modification process results in modified openings with increased critical dimensions to the initial opening pattern, demonstrating the effectiveness of the sequential directional processing approach for achieving enhanced pattern density and improved device performance characteristics.

FIGS. 7A-7B illustrate a cross-sectional side view and a top view of a substrate 750 at two steps of the CD modification process that performed push etches on both sidewalls of the openings and how critical dimensions of the openings were formed differently in different directions in the substrate 750 according to embodiments of the disclosure. The bidirectional push etch approach enables symmetric expansion of the openings in multiple directions, and the substrate 750 in FIG. 7A comprises rectangular openings having undergone a first bidirectional push etch to form first openings 710 having a first critical dimension CD₁, and the substrate 750 in FIG. 7B comprises rectangular openings having undergone a second bidirectional push etch to form second openings 720 having a second critical dimension CD₂ which is larger than the first openings 710. The substrate 750 comprises alternating first layers 704 and second layers 706 disposed over a substrate base 702 which may be as previously described for the similarly labeled layers for the substrate 500 in FIGS. 5A-5K above. Similarly, the substrate 750 comprises a third layer 708 which may be as previously described for the third layer 508 or the third layer 108 above.

FIG. 7A shows the substrate 750 comprising first openings 710 comprising a first critical dimension CD₁ which has an associated X′ component and a Y′ component, which is shown in the top view as CD_{1X′} and CD_{1Y′} respectively. The bidirectional push etch and the vertical etch of the CD modification process modified the critical dimensions in both an X′ and Y′ direction, but not the same in both directions. Similarly, FIG. 7B shows the substrate 750 comprising second openings 720 comprising a second critical dimension CD₂ which has an associated X′ component and a Y′ component, which is shown in the top view as CD_{2X′} and CD_{2Y′} respectively.

As illustrated, the critical dimension of second openings 720 increased in the X′ direction, but decreased in the Y′ direction. However, the bidirectional push etches of this disclosure enable the formation of modified openings such that the ratio of Y′ critical dimension to X′ critical dimension of modified openings comprising a second geometry compared to the ratio of Y′ critical dimension to X′ critical dimension of unmodified openings comprising a first geometry increases. In other words, FIGS. 7A-7B illustrate how the ratio CD_{2Y′}/CD_{2X′} of the second openings 720 is greater than the ratio CD_{1Y′}/CD_{1X′} of the first openings 710.

FIG. 8 illustrates a block diagram which may be used to describe a processing system 80 capable of implementing the methods for CD modification of this disclosure. The processing system 80 comprises a scanning chamber 800 that houses a scanning mechanism comprising actuators, moving parts, hinges, and a substrate holder 810, collectively referred to as a wafer scanner 820; a processing chamber 850 where a substrate 840 (loaded onto the wafer scanner 820) may intersect a focused beam 841 emitted over an area 845 of the substrate 840 by a processing nozzle 843 for processing the substrate 840, and comprising a processing tool 849 configured to produce the focused beam 841 emitted by the processing nozzle 843 using a gas mixture; and a rotatable feedthrough 830 (or a tilt drive) between the scanning chamber 800 and the process chamber 850 through which a moving part of the wafer scanner 820 can access and move the substrate 840 within the processing chamber 850. The combined continuous motion of the movable parts of the wafer scanner 820 and discrete rotary motion of the scanning chamber 800 using the rotatable feedthrough 830 may provide the desired movements of the substrate 840 through the focused beam 841 to complete the push etches of the CD modification process of this disclosure.

In various embodiments, the processing tool 849 may use a gas cluster system to emit gas clusters. In one or more embodiments, the focused beam 841 may comprise radicals, ions, neutral species, gas clusters, or combinations of these. Accordingly, in this embodiment, the scanning chamber 800, the wafer scanner 820, and the rotatable feedthrough 830 are together referred to as the scanning apparatus 700. The full range of motion of the wafer scanning apparatus 700 and of the substrate 840 relative to the focused beam 841 impinging on its surface is described in further detail below.

In some embodiments, the substrate holder 810 may be electrically coupled to an RF power supply (not shown) to generate a plasma as the focused beam 841. The RF power supply (not shown) may be used to apply a bias voltage of variable processing parameters to the substrate holder 810 to process the substrate 840 using the focused beam 841. The variable processing parameters of the bias voltage to the substrate holder 810 may be used to control the material removal rate of various layers comprising different materials on the substrate 840 at the desired processing angles for the push etches of the CD modification process. For example, an amplitude, a frequency, and a waveform (such as square-wave, or sine-wave, or others) are all variable processing parameters which may be adjusted according to a processing recipe to control the material removal rate from the substrate 840 by the focused beam 841.

An additional processing parameter which may be configured to control the material removal rate and the modification of the opening geometry is a gas mixture used to form the focused beam 841. In other words, the gas mixture may comprise different mixtures of gases specifically tailored to the material of the substrate 840 to be removed (or etched) through the etch pushes or lateral etching steps of the CD modification process. For example, in various embodiments, the gas mixture may comprise a mixture of SF₆ and O₂ to form the focused beam 841. Other potential gas mixtures may comprise any material selective gas mixture capable of achieving anisotropic etch profiles, such as gas mixtures comprising oxygen-based etchants, or fluorine-based etchants.

The processing system 80 further comprises a load lock 880, where substrates for processing may be placed, and a wafer transfer chamber 870, as illustrated in FIG. 8. The substrate 840 may be transported from the load lock 880 to the substrate holder 810 of the wafer scanner 820 using, for example, an (r, θ, z) robotic arm located in the wafer transfer chamber 870. A wafer transfer window in the processing chamber 850 may be used to transfer the substrate 840 from the wafer transfer chamber 870 to the substrate holder 810.

The processing system 80 further comprises a controller 801 to control the rotary drives of the scanning apparatus 700, the bias voltage applied to the substrate holder 810 by the RF power supply 855, and the processing tool 849 to control the generation of the focused beam 841 (such as the ignition of the gas mixture described above, or the generation of a gas cluster beam (GCB)). The controller 801 may be used to implement the processing method of this disclosure by executing instructions stored in a memory 881. The memory 881 may be any suitable storage device capable of storing the instructions to be executed by the controller to implement the processing method embodiments of this disclosure.

As illustrated in FIG. 8, the processing system 80 may comprise a vacuum system 890 connected to the scanning chamber 800, the process chamber 850, the wafer transfer chamber 870, and the load lock 880. The connection between the scanning chamber 800 and the processing chamber 850 may be controlled by a rotary seal in the rotatable feedthrough 830, and the connections between the load lock 880, the wafer transfer chamber 870, and the processing chamber 850 may be controlled by two gate valves 860, as indicated schematically in FIG. 8. In one embodiment, this allows each chamber of the processing system 80 to be isolated and maintained at an independently controlled pressure using, for example, throttle valves.

The processing system 80 may be used to perform the substrate processing method of this disclosure to perform a CD modification process to modify a feature pattern on the substrate 840 using the scanning apparatus 700. In one embodiment, two rotary drives (a first rotary drive 802 and a second rotary drive 804) are used as the primary actuators of the wafer scanner 820. Synchronous angular displacements of the first and the second rotary drives 802 and 804 may be accurately computed in accordance with a desired planar trajectory of the center of the substrate holder 810, and subsequently used by a controller 801 to generate the computed synchronized rotational motions with high precision using, for example, electronically controllable motors. The synchronized pair of rotations actuated by the first and the second rotary drives 802 and 804 is converted to a target scan trajectory of the center of the substrate holder 810 via various other moving parts of the wafer scanner 820. The trajectory of the substrate holder 810, hence, also the trajectory of the substrate 840 loaded onto the substrate holder 810, is substantially coplanar with (or parallel to) the processing surface of the substrate 840.

In one embodiment, the rotational motion of the first and the second rotary drives 802 and 804 may be translated to a planar motion along the plane of the surface of substrate 840 using a bar-and-hinge system comprising five bar links (a first bar link 821, a second bar link 823, a third bar link 824, a fourth bar link 825, and a belted fifth bar link 822), and three hinges (a first hinge 805, a second hinge 806, and a third hinge 807) about which the bar links can rotate.

The belted fifth bar link 822 comprises a bar link 826 and a motorized belt-and-pulley system 827 in the bar link 826. The motorized belt-and-pulley system 827 may be used to orient the substrate 840 by rotating the planar surface of the substrate holder 810 along with the substrate 840. In various other embodiments, the mechanism used to rotate the substrate holder 810 may be implemented differently, as discussed in further detail below.

The fourth bar link 825 is attached to the first rotary drive 802 and, at the opposite end, to a free moving first hinge 805. The first bar link 821, attached to the second rotary drive 804, has its opposite end connected to another free moving third hinge 807. The pair of synchronized rotations of the actuated first and fourth bar links 821 and 825 (synchronized by the controller, as described above) causes a respective synchronized pair of displacements of the first and the third hinges 805 and 807. The first and the third hinges 805 and 807 transmit the motion to other bar links attached to the first and the third hinges 805 and 807.

First hinge 805 is attached to one end of the third bar link 824, and third hinge 807 is attached to one end of the second bar link 823. The opposite ends of the second and the third bar links 823 and 824 are both connected to the second hinge 806. This causes a motion of the second hinge 806 conforming to the trigonometric relations between the angles of a triangle having two sides determined by the lengths of two bar links (second and third bar links 823 and 824) and the third side being the line segment connecting the first and the third hinges 805 and 807. The distance between the first and the third hinges 805 and 807 is determined by a combination of their synchronized displacements described above. In one embodiment, the repositioning of second hinge 806 determines the trajectory of the center of the substrate holder 810 (and of the substrate 840), as explained herein.

One end of the belted fifth bar link 822 has been attached to the substrate holder 810 and the opposite end is attached to the third hinge 807 and the second bar link 823. The connection between the second bar link 823 and the belted fifth bar link 822 allows the two-bar combination to pivot around the third hinge 807 while the angle formed by the two bars is held fixed. Accordingly, in this embodiment of the wafer scanner 820, the location of the center of the substrate holder 810 is uniquely determined by the combined positions of second and third hinges 806 and 807 and the combined lengths of the second bar link 823 and the belted fifth bar link 822. In various embodiments, the rotatable feedthrough 830 combined with the rotatable motions enabled by the wafer scanner 820 enable the various processing angles for the push etches along desired sidewalls of openings in the substrate 840, such as described for the substrate 100 of FIGS. 1A-1H or the substrate 500 of FIGS. 5A-5K above.

FIGS. 9-10 are flowcharts illustrating embodiment methods for processing a substrate using a CD modification process in accordance with embodiments of this disclosure. The methods of FIGS. 9-10 may be combined with other methods and performed using suitable systems and apparatuses as described herein, such as the scanning apparatus 700 of the processing system 80 of FIG. 8. Although shown in a logical order, the arrangement and numbering of the steps of FIGS. 9-10 are not intended to be limiting.

Referring to FIG. 9, step 910 of a method 900 for processing a substrate using a CD modification process receives the substrate comprising a patterned mask disposed over a layer stack comprising a second layer disposed over a first layer, the patterned mask comprising a feature pattern. Step 920 of the method 900 etches the substrate to transfer the feature pattern to the second layer and form first openings that expose the first layer, the first openings comprising a first critical dimension.

Step 930 of the method 900 exposes a first sidewall of the first openings to a first focused beam at a first processing angle for a first processing time to extend the first openings in a first direction and form second openings, the second openings comprising a second critical dimension larger than the first critical dimension. After forming the second openings, in step 940, the method 900 etches the substrate to transfer the second openings through the first layer and form third openings, the third openings comprising the second critical dimension.

Still referring to FIG. 9, in step 950, the method 900 exposes the first sidewall of the third openings to a second focused beam at a second processing angle for a second processing time to form fourth openings, the fourth openings comprising a third critical dimension larger than the first critical dimension and the second critical dimension. In various embodiments, the steps described for the method 900 may be the steps described for the substrate 100 of FIGS. 1A-1H or the substrate 500 of FIGS. 5A-5K.

Now referring to FIG. 10, step 1010 of a method 1000 for performing a CD modification process on a substrate receives the substrate comprising a patterned layer with first pattern features comprising a first geometry. In step 1020, the method 1000 exposes the patterned layer to a focused beam at a first processing angle for a first processing time to extend the first pattern features in a first direction and form extended pattern features. And in step 1030, the method 1000, after the first processing time, exposes the extended pattern features to the focused beam at a second processing angle different from the first processing angle for a second processing time to further extend the extended pattern features in a second direction and form modified pattern features, the second direction being different from the first direction, the modified pattern feature comprising a second geometry different from the first geometry. Similarly, in various embodiments, the method 1000 may be the method described for the substrate 100 using FIGS. 1A-1H or the method describe for the substrate 500 using FIGS. 5A-5K which use a bidirectional CD modification process.

Example embodiments of the invention are described below. Other embodiments can also be understood from the entirety of the specification as well as the claims filed herein.

Example 1. A method for processing a substrate includes receiving the substrate including a patterned mask disposed over a layer stack including a second layer disposed over a first layer, the patterned mask including a feature pattern, and etching the substrate to transfer the feature pattern to the second layer and form first openings that expose the first layer, the first openings including a first critical dimension. The method further includes exposing a first sidewall of the first openings to a first focused beam at a first processing angle for a first processing time to extend the first openings in a first direction and form second openings, the second openings including a second critical dimension larger than the first critical dimension, and etching the substrate to transfer the second openings through the first layer and form third openings, the third openings including the second critical dimension. And the method further includes exposing the first sidewall of the third openings to a second focused beam at a second processing angle for a second processing time to form fourth openings, the fourth openings including a third critical dimension larger than the first critical dimension and the second critical dimension.

Example 2. The method of example 1, where the feature pattern includes contact holes, and the fourth openings include line-space patterns.

Example 3. The method of one of examples 1 or 2, where the fourth openings form continuous trenches extending across the substrate.

Example 4. The method of one of examples 1 to 3, further including exposing a second sidewall of the first openings to a third focused beam at a third processing angle to extend the first openings in a second direction different from the first direction.

Example 5. The method of one of examples 1 to 4, further including, before etching the substrate to transfer the second openings through the first layer, and after exposing the first sidewall of the first openings to a first focused beam, exposing a second sidewall of the second openings to a modified first focused beam at a modified first processing angle for a modified first processing time to form modified second openings, the second sidewall being different from the first sidewall, and after exposing the first sidewall of the third openings to a second focused beam, exposing the second sidewall of the fourth openings to a modified second focused beam at a modified second processing angle for a modified second processing time to form modified fourth openings.

Example 6. The method of one of examples 1 to 5, further including repeating the exposing of the first sidewall to additional focused beams at different processing angles to connect adjacent openings.

Example 7. The method of one of examples 1 to 6, where the exposing the first sidewall of the first openings to the first focused beam etches a second material of the second layer at a second etch rate and etches a first material of the first layer at a first etch rate, the second etch rate being larger than the first etch rate.

Example 8. The method of one of examples 1 to 7, where the second layer includes a carbon-based material, the first layer includes silicon oxide, the first focused beam includes an oxygen gas cluster beam, and the second focused beam includes an oxygen gas cluster beam.

Example 9. The method of one of examples 1 to 8, where the first layer includes an inorganic material and the second layer includes an organic material.

Example 10. The method of one of examples 1 to 9, where the first focused beam and the second focused beam include neutral atoms, neutral molecules, gas clusters, ions, radicals, meta-stables, or combinations thereof.

Example 11. The method of one of examples 1 to 10, where the first focused beam and the second focused beam include gas cluster beams, the gas cluster beams including oxygen-based species or fluorine-based species.

Example 12. A method for pattern modification includes receiving a substrate including a patterned layer with first pattern features including a first geometry, and exposing the patterned layer to a focused beam at a first processing angle for a first processing time to extend the first pattern features in a first direction and form extended pattern features. And the method further includes, after the first processing time, exposing the extended pattern features to the focused beam at a second processing angle different from the first processing angle for a second processing time to further extend the extended pattern features in a second direction and form modified pattern features, the second direction being different from the first direction, the modified pattern features including a second geometry different from the first geometry.

Example 13. The method of example 12, where the focused beam includes neutral atoms, neutral molecules, gas clusters, ions, radicals, meta-stables, or combinations thereof.

Example 14. The method of one of examples 12 or 13, where the first processing angle varies between 15° and 85° relative to a surface normal of a plane that is parallel to a surface of the substrate, and the second processing angle varies between 15° and 85° relative to the surface normal.

Example 15. The method of one of examples 12 to 14, where the focused beam includes a gas cluster beam.

Example 16. The method of one of examples 12 to 15, where the gas cluster beam includes oxygen-based species.

Example 17. The method of one of examples 12 to 16, where the gas cluster beam includes fluorine-based species.

Example 18. The method of one of examples 12 to 17, where the first geometry includes circular openings and the second geometry includes elongated openings.

Example 19. The method of one of examples 12 to 18, where the first geometry includes contact holes, and where the second geometry includes trenches.

Example 20. The method of one of examples 12 to 19, where the first pattern features have a first pitch and the modified pattern features have a second pitch smaller than the first pitch.

Example 21. The method of one of examples 12 to 20, where the modified pattern features include connected adjacent pattern features.

Example 22. The method of one of examples 12 to 21, where the patterned layer includes an organic material or a carbon-based material.

Example 23. The method of one of examples 12 to 22, where the substrate further includes an underlying layer disposed beneath the patterned layer, and where the patterned layer includes an organic material and the underlying layer includes an inorganic material.

Example 24. The method of one of examples 12 to 23, further including repeating the exposing steps to connect adjacent pattern features to form continuous features.

Example 25. A system for patterning a substrate includes a processing chamber including a processing tool and a substrate holder, the processing tool configured to emit a focused beam, a scanning tool coupled to the substrate holder in the processing chamber, the scanning tool configured to scan the substrate holder along a plane that is parallel with a surface of the substrate holder that is tilted at a processing angle relative to a beam direction of the processing tool, and a controller coupled to the scanning tool, the processing tool, and a memory storing instructions to be executed in the controller. The instructions when executed enable the controller to receive the substrate including a patterned mask disposed over a layer stack including a second layer disposed over a first layer on the substrate holder, the patterned mask including a feature pattern, etch the substrate to transfer the feature pattern to the second layer and form first openings that expose the first layer, the first openings including a first critical dimension, expose a first sidewall of the first openings to a first focused beam at a first processing angle for a first processing time to extend the first openings in a first direction and form second openings using the processing tool, the second openings including a second critical dimension larger than the first critical dimension, etch the substrate to transfer the second openings through the first layer and form third openings, the third openings including the second critical dimension, and expose the first sidewall of the third openings to a second focused beam at a second processing angle for a second processing time to form fourth openings using the processing tool, the fourth openings including a third critical dimension larger than the first critical dimension and the second critical dimension.

Example 26. The system of example 25, where the processing tool includes a gas cluster beam tool.

Example 27. The system of one of examples 25 or 26, where the substrate holder includes an electrostatic chuck or a vacuum chuck.

Example 28. The system of one of examples 25 to 27, where the scanning tool includes a first rotary drive disposed in a scanning chamber and configured to rotate around a first axis, a second rotary drive disposed in the scanning chamber and configured to rotate around the first axis synchronously with the first rotary drive, a tilt drive configured to angle a normal direction of the substrate holder relative to the beam direction of the focused beam at the processing angle, and a bar-and-hinge system disposed in the scanning chamber and mechanically coupled to the substrate holder, the hinge system configured to translate a rotary motion of the first rotary drive and the second rotary drive to a planar motion of the substrate holder.

Example 29. The system of one of examples 25 to 28, where the bar-and-hinge system includes a first passive hinge, a second passive hinge, and a third passive hinge, the first, the second, and the third passive hinges being configured to rotate around the first axis, a first bar link rotatably coupling the second rotary drive to the third passive hinge, a second bar link rotatably coupling the second passive hinge with the third passive hinge, a third bar link rotatably coupling the first passive hinge with the second passive hinge, a fourth bar link rotatably coupling the first rotary drive to the first passive hinge, and a belted bar link supporting the substrate holder, the belted bar link being coupled to the second bar link through the third passive hinge.

While the inventive aspects are described primarily in the context of semiconductor contact hole and line-space pattern formation, it should also be appreciated that these inventive aspects may also apply to other pattern transformation applications in microfabrication. In particular, aspects of this disclosure may similarly apply to photonic device patterning, microelectromechanical systems (MEMS) fabrication, and advanced packaging applications where precise pattern pitch control and feature extension are beneficial.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments may comprise combinations of embodiments discussed in FIGS. 1-3, and 5-11. It is therefore intended that the appended claims encompass any such modifications or embodiments.

What is claimed is:

1. A method for processing a substrate, the method comprising:
receiving the substrate comprising a patterned mask disposed over a layer stack comprising a second layer disposed over a first layer, the patterned mask comprising a feature pattern;
etching the substrate to transfer the feature pattern to the second layer and form first openings that expose the first layer, the first openings comprising a first critical dimension;
exposing a first sidewall of the first openings to a first focused beam at a first processing angle for a first processing time to extend the first openings in a first direction and form second openings, the second openings comprising a second critical dimension larger than the first critical dimension;
etching the substrate to transfer the second openings through the first layer and form third openings, the third openings comprising the second critical dimension; and
exposing the first sidewall of the third openings to a second focused beam at a second processing angle for a second processing time to form fourth openings, the fourth openings comprising a third critical dimension larger than the first critical dimension and the second critical dimension.

2. The method of claim 1, wherein the feature pattern comprises contact holes, and the fourth openings comprise line-space patterns or continuous trenches.

3. The method of claim 1, further comprising exposing a second sidewall of the first openings to a third focused beam at a third processing angle to extend the first openings in a second direction different from the first direction.

4. The method of claim 1, further comprising:
before etching the substrate to transfer the second openings through the first layer, and after exposing the first sidewall of the first openings to a first focused beam, exposing a second sidewall of the second openings to a modified first focused beam at a modified first processing angle for a modified first processing time to form modified second openings, the second sidewall being different from the first sidewall; and
after exposing the first sidewall of the third openings to a second focused beam, exposing the second sidewall of the fourth openings to a modified second focused beam at a modified second processing angle for a modified second processing time to form modified fourth openings.

5. The method of claim 1, further comprising repeating the exposing of the first sidewall to additional focused beams at different processing angles to connect adjacent openings.

6. The method of claim 1, wherein the exposing the first sidewall of the first openings to the first focused beam etches a second material of the second layer at a second etch rate and etches a first material of the first layer at a first etch rate, the second etch rate being larger than the first etch rate.

7. The method of claim 1, wherein the second layer comprises a carbon-based material, the first layer comprises silicon oxide, the first focused beam comprises an oxygen gas cluster beam, and the second focused beam comprises an oxygen gas cluster beam.

8. The method of claim 1, wherein the first layer comprises an inorganic material and the second layer comprises an organic material, and wherein the first focused beam and the second focused beam comprise gas cluster beams, the gas cluster beams comprising oxygen-based species or fluorine-based species.

9. The method of claim 1, wherein the first focused beam and the second focused beam comprise neutral atoms, neutral molecules, gas clusters, ions, radicals, meta-stables, or combinations thereof.

10. A method for pattern modification, the method comprising:
receiving a substrate comprising a patterned layer with first pattern features comprising a first geometry;
exposing the patterned layer to a focused beam at a first processing angle for a first processing time to extend the first pattern features in a first direction and form extended pattern features; and
after the first processing time, exposing the extended pattern features to the focused beam at a second processing angle different from the first processing angle for a second processing time to further extend the extended pattern features in a second direction and form modified pattern features, the second direction being different from the first direction, the modified pattern features comprising a second geometry different from the first geometry.

11. The method of claim 10, wherein the focused beam comprises neutral atoms, neutral molecules, gas clusters, ions, radicals, meta-stables, or combinations thereof, and wherein the patterned layer comprises an organic material or a carbon-based material.

12. The method of claim 10, wherein the first processing angle varies between 15° and 85° relative to a surface normal of a plane that is parallel to a surface of the substrate, and the second processing angle varies between 15° and 85° relative to the surface normal.

13. The method of claim 10, wherein the focused beam comprises a gas cluster beam, the gas cluster beam comprising oxygen-based species or fluorine-based species.

14. The method of claim 10, wherein the first geometry comprises circular openings or contact holes, and wherein the second geometry comprises elongated openings or trenches.

15. The method of claim 10, wherein the first pattern features have a first pitch and the modified pattern features have a second pitch smaller than the first pitch.

16. The method of claim 10, wherein the modified pattern features comprise connected adjacent pattern features.

17. The method of claim 10, wherein the substrate further comprises an underlying layer disposed beneath the patterned layer, and wherein the patterned layer comprises an organic material and the underlying layer comprises an inorganic material.

18. A system for patterning a substrate, the system comprising:
a processing chamber comprising a processing tool and a substrate holder, the processing tool configured to emit a focused beam;
a scanning tool coupled to the substrate holder in the processing chamber, the scanning tool configured to scan the substrate holder along a plane that is parallel with a surface of the substrate holder that is tilted at a processing angle relative to a beam direction of the processing tool; and
a controller coupled to the scanning tool, the processing tool, and a memory storing instructions to be executed in the controller, the instructions when executed enable the controller to:
receive the substrate comprising a patterned mask disposed over a layer stack comprising a second layer disposed over a first layer on the substrate holder, the patterned mask comprising a feature pattern,
etch the substrate to transfer the feature pattern to the second layer and form first openings that expose the first layer, the first openings comprising a first critical dimension,
expose a first sidewall of the first openings to a first focused beam at a first processing angle for a first processing time to extend the first openings in a first direction and form second openings using the processing tool, the second openings comprising a second critical dimension larger than the first critical dimension,
etch the substrate to transfer the second openings through the first layer and form third openings, the third openings comprising the second critical dimension, and
expose the first sidewall of the third openings to a second focused beam at a second processing angle for a second processing time to form fourth openings using the processing tool, the fourth openings comprising a third critical dimension larger than the first critical dimension and the second critical dimension.

19. The system of claim 18, wherein the processing tool comprises a gas cluster beam tool, and wherein the substrate holder comprises an electrostatic chuck or a vacuum chuck.

20. The system of claim 18, wherein the scanning tool comprises:
a first rotary drive disposed in a scanning chamber and configured to rotate around a first axis;
a second rotary drive disposed in the scanning chamber and configured to rotate around the first axis synchronously with the first rotary drive;
a tilt drive configured to angle a normal direction of the substrate holder relative to the beam direction of the focused beam at the processing angle; and
a bar-and-hinge system disposed in the scanning chamber and mechanically coupled to the substrate holder, the hinge system configured to translate a rotary motion of the first rotary drive and the second rotary drive to a planar motion of the substrate holder.
